(19) United States
(12) Patent Application Publication
(10) Pub. No.: US 2014/0140124 A1
(43) Pub. Date: May 22, 2014

(54) RESISTIVE MEMORY DEVICE HAVING SELECTIVE SENSING OPERATION AND ACCESS CONTROL METHOD THEREOF

(71) Applicants: Dong-Seok KANG, Seoul (KR); CHANKYUNG KIM, Hwaseong-si (KR); YUNSANG LEE, Yongin-si (KR); Soo-Ho CHA, Seoul (KR)

(72) Inventors: Dong-Seok KANG, Seoul (KR); CHANKYUNG KIM, Hwaseong-si (KR); YUNSANG LEE, Yongin-si (KR); Soo-Ho CHA, Seoul (KR)

(21) Appl. No.: 14/078,530

(22) Filed: Nov. 13, 2013

Related U.S. Application Data
(60) Provisional application No. 61/728,853, filed on Nov. 21, 2012.

(30) Foreign Application Priority Data
Feb. 14, 2013 (KR) 10-2013-0015891

(51) Int. Cl. G11C 13/00

(52) U.S. Cl. CPC G11C 13/004
USPC 365/148; 365/158

(57) ABSTRACT

A method of controlling a read operation of a resistive memory device is provided which includes activating at least one of a plurality of word lines in response to a first command; after receiving a second command, sensing data of a memory cell, corresponding to a selected page, from among all memory cells connected with the activated word line through a corresponding bit line sense amplifier; and outputting the sensed data as read data according to a sensing output control signal.

### CROSS-REFERENCE TO RELATED APPLICATIONS

A claim for priority under 35 U.S.C. §119 is made to U.S. Provisional Application No. 61/728,853 filed Nov. 21, 2012, and Korean Patent Application No. 10-2013-0015891 filed Feb. 14, 2013, in the Korean Intellectual Property Office, the entire contents of each of which are hereby incorporated by reference.

### BACKGROUND

The inventive concept relates to a semiconductor memory, and more particularly, to a resistive memory device.

A semiconductor memory device such as a random access memory (hereinafter, referred to as DRAM) is often used as a main memory of an electronic device (e.g., mobile device or computer).

A memory system including the volatile semiconductor memory device and a memory control device may be embedded in or connected with a host device such as a microprocessor.

A magnetic random access memory (hereinafter, referred to as an MRAM) is a nonvolatile memory device known to overcome certain drawbacks of the DRAM being a volatile memory. The MRAM is nonvolatile, and has high-integration, high-speed, and low-power characteristics.

In general, a magnetic memory cell in the MRAM may be formed of an access transistor to perform a switching operation and a magnetic tunnel junction (MTJ) element to store data. The MTJ element may have magneto resistance (MR) varied according to magnetization directions of two ferromagnetic substances. In the MRAM, data stored at the MTJ element may be determined as ‘1’ or ‘0’ by sensing a variation in the magneto resistance.

### SUMMARY

Example embodiment are directed to methods of controlling a read operation of a resistive memory device which may comprise receiving a first command; activating a first word line of a plurality of word lines in response to receiving the first command; receiving a second command after the first command; in response to receiving a second command, sensing data of only a first portion of memory cells connected to the first word line while the first word line remains activated; and outputting the sensed data as read data.

A first time period from an input of the first command until an input of the second command may be shorter than a second time period from an input of the second command until an output of the read data.

Methods may further comprise receiving a third command after receiving the second command; in response to receiving a third command, sensing data of only a second portion of memory cells operatively connected to the first word line while the first word line is activated in response to the first command.

Sensing data may comprise sensing data with a bit line sense amplifier that is shared by plural bit lines.

The methods may further comprise connecting the bit line sense amplifier to one of the plural bit lines in response to the second command.

The first word line may be activated after a column address is received.

The memory cells may be magnetic memory cells.

The first portion of the first word line may be selected from plural portions of the first word line by decoding at least a part of row address.

Methods of controlling a read operation of a resistive memory device may comprise activating a first word line, identified with a first command, from among a plurality of word lines; sensing data of only a first portion of memory cells connected to the activated first word line, the first portion of memory cells being selected by a page selection signal, from among all memory cells connected with the activated first word line; and outputting the sensed data as read data in response to a column selection control signal.

The column selection control signal may be activated by decoding at least a part of a column address.

A first time period from an input of the first command until an input of the second command may be shorter than a second time period from an input of the second command until an output of the read data.

The methods may include, while the first word line is activated, receiving a sequence of second commands and sequentially sensing respective portions of memory cells connected to the activated first word line in response to corresponding ones of the received sequence of second commands.

The sensing of data of the first portion of memory cells connected to the activated first word line may comprise sensing data with a bit line sense amplifier that is shared by bit lines belonging to different pages.

The sensing of data of the first portion of memory cells connected to the activated first word line may comprise sensing data with a plurality of bit line sense amplifiers each being connected to bit lines of plural pages, and the bit line sense amplifiers may be distributed throughout a sub memory cell array.

The first word line may be activated after a column address is received.

The memory cell may be an STT-MRAM cell.

The sensing of data of the first portion of memory cells connected to the activated first word line may comprise sensing data with a bit line sense amplifier that is shared by bit lines belonging to different pages, and wherein the first word line and a bit line connected to the bit line sense amplifier may be selected by decoding at least a part of a row address.

Methods of controlling a resistive memory device may comprise activating at least a first of a plurality of word lines in response to a first command; in response to a received second command and received write data, activating a column selection control signal; and driving bit line sense amplifiers such that the write data is stored at memory cells of the first word line corresponding to a selected page identified with the second command, from among all memory cells connected with the activated word line.

The bit line sense amplifiers may be enabled by corresponding bit line sense amplifier enable signals, and the column selection control signal and the bit line sense amplifier enable signals may be activated at a same time period.

An operation of sensing cell data stored in the memory cells may be inhibited in response to receiving the second command.

While the first word line is activated in response to the first command, a third command may be received and in response to the third command, a first page of data of the first word line of plural pages of the first word line may be sensed.

The methods may further comprise, while the first word line is activated in response to the first command, receiving a series of third commands, and in response to each of the third commands, sensing a corresponding page of data of the first word line of plural pages of the first word line.

Each of the bit line sense amplifiers may be connected to bit lines of different pages.

Memory cells corresponding to the selected page may be selected by decoding at least a part of a row address.

Resistive memory devices are also disclosed and my comprise a memory cell array including a plurality of memory banks each having a plurality of sub memory cell arrays where memory cells are disposed at intersections of word lines and bit lines; a plurality of bit line sense amplifiers each configured to be connected to bit lines of different pages, the bit line sense amplifiers being distributed through each of the sub memory cell arrays; a first decoder configured to generate a page selection signal such that, at least within a first sub memory cell array of the sub memory cell arrays, each of the plurality of bit line sense amplifiers is connected to a corresponding bit line of a first page of the different pages; and a second decoder configured to generate a word line selection signal for selecting one of the word lines and to generate a sub block selection signal for selectively connecting a sensing output terminal of each of the bit line sense amplifiers with a corresponding input/output line.

The first decoder may be configured to generate the page selection signal by decoding at least a part of a part of row address bits.

The second decoder may be a decoder configured to decode a row address and a column address.

The bit line sense amplifiers may be configured to be independently enabled in response to a receipt of a column address and a read command such that data of memory cells connected with corresponding bit lines selected by the page selection signal is sensed.

Methods are disclosed of reading a resistive memory device, the memory device comprising a plurality of word lines, a plurality of bit lines, and memory cells each connected with one of the word lines and one of the bit lines, the methods may comprise activating a first word line of the plurality of word lines, the first word line being connected to a plurality of resistive memory cells; during a first time period, sensing data of only a first group of the resistive memory cells connected to the first word line while the first word line is activated; and during a second time period, sensing data of only a second group of the resistive memory cells connected to the first word line.

The methods may further comprise selectively connecting a plurality of bit line sense amplifiers to a first group of bit lines connected to the first group of resistive memory cells to sense data of the first group of resistive memory cells; and selectively connecting the plurality of bit line sense amplifiers to a second group of bit lines connected to the second group of resistive memory cells to sense data of the second group of resistive memory cells.

The methods may further comprise receiving first, second and third commands, wherein activation of the first word line may be responsive to the first command, wherein selectively connecting the plurality of bit line sense amplifiers to the first group of bit lines may be responsive to the second command, and wherein selectively connecting the plurality of bit line sense amplifiers to the second group of bit lines may be responsive to the third command.

In example embodiments, at the page open, a bit size of a page is changed by changing the number of row address bits to be decoded and the number of column address bits to be decoded.

Systems and devices are also disclosed that implement such operations.

### BRIEF DESCRIPTION OF THE FIGURES

The above and other features of the inventive concept will become more apparent from the description of the detailed description of the exemplary embodiments with reference to the accompanying drawings, in which:

FIG. 1 is a block diagram schematically illustrating a resistive memory device according to an embodiment of the inventive concept;

FIG. 2 is a diagram schematically illustrating arrangement of a typical memory cell array;

FIG. 3 is a block diagram schematically illustrating a memory cell array according to an embodiment of the inventive concept;

FIG. 4 is a comparison table of address use associated with operations of FIGS. 2 and 3;

FIG. 5 is a block diagram schematically illustrating a resistive memory device including a memory cell array of FIG. 1;

FIG. 6 is a diagram illustrating a memory bank structure of a memory cell array of FIG. 5 and a data input/output path;

FIG. 7 is a diagram schematically illustrating a full chip structure according to an embodiment of the inventive concept;

FIG. 8 is a detailed diagram of a sense amplifier area of FIG. 7;

FIG. 9 is a diagram for describing an example in which a page size of a memory cell array of FIG. 3 is changed;

FIG. 10 is a block diagram schematically illustrating a memory cell array according to another embodiment of the inventive concept;

FIG. 11 is a diagram schematically illustrating connection between a shared bit line sense amplifier and a sub memory cell array having a cross-point arrangement structure;

FIG. 12 is a read operation timing diagram according to FIG. 2;

FIG. 13A shows a read operation timing diagram of FIG. 12 and FIG. 13B shows an exemplary read operation timing diagram according to FIG. 1, 3, or 5;

FIGS. 14A, 14B and 14C shows exemplary read operation timing diagrams;

FIG. 15 is a write operation timing diagram according to FIG. 1, 3 or 5;

FIG. 16 is a tCCD sequential read operation timing diagram according to FIG. 1, 3 or 5;

FIG. 17 is an operating timing diagram showing the contrast between a read control operation and a write control operation of a resistive memory device of FIG. 5;

FIG. 18 is a diagram illustrating an operating principle of a memory cell applicable to the inventive concept;

FIG. 19 is an equivalent circuit diagram of a memory cell of FIG. 18;

FIG. 20 is a block diagram schematically illustrating a mobile device according to an embodiment of the inventive concept;

FIG. 21 is a block diagram schematically illustrating a smart card including a magnetic memory device according to an embodiment of the inventive concept;

FIG. 22 is a block diagram schematically illustrating a memory system including a magnetic memory device according to an embodiment of the inventive concept;

FIG. 23 is a block diagram schematically illustrating a memory card according to an embodiment of the inventive concept;

FIG. 24 is a block diagram schematically illustrating an information processing system according to an embodiment of the inventive concept;

FIG. 25 is a block diagram schematically illustrating a solid state drive (SSD) according to an embodiment of the inventive concept is applied;

FIG. 26 is a block diagram schematically illustrating a computing system according to an embodiment of the inventive concept;

FIG. 27 is a block diagram schematically illustrating an electronic device according to an embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques may not described with respect to some of the embodiments of the inventive concept. It is emphasized that the disclosed example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Embodiments disclosed therein may include the features of other disclosed embodiments. Note that details of data access operations associated with a DRAM and an MRAM and internal function circuits associated with data sensing, reading and writing operations may be skipped to prevent the inventive concept from becoming ambiguous.

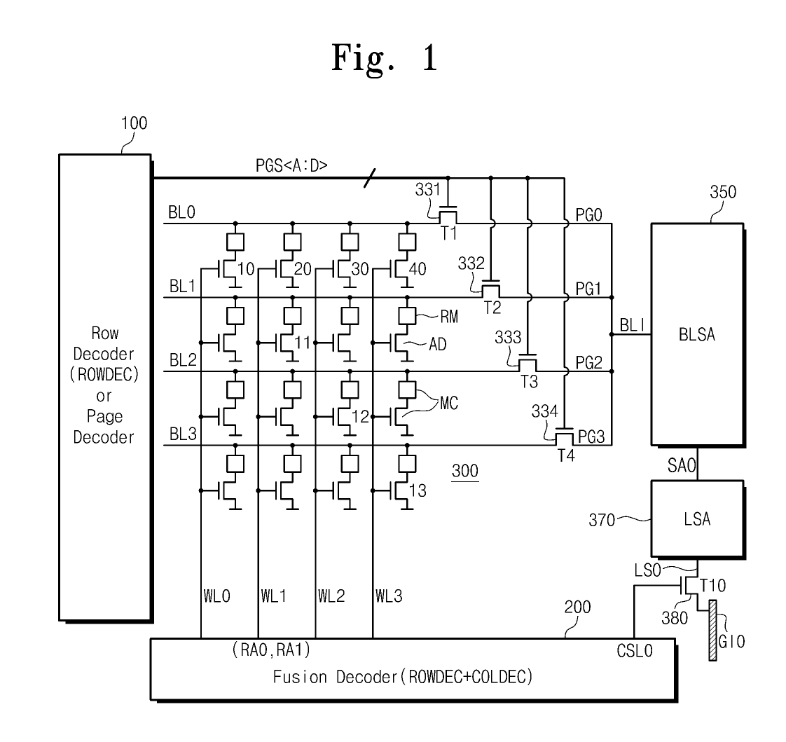

FIG. 1 is a block diagram schematically illustrating a resistive memory device according to an embodiment of the inventive concept.

Referring to FIG. 1, a row decoder 100, a fusion decoder 200, a memory cell array 300, and a bit line sense amplifier 350 are illustrated.

A memory cell MC may be formed of an access element AD and a variable resistance element RM. For example, in case of an MRAM, the memory cell MC may be a magnetic memory cell, and the access element AD may be formed of a MOS transistor or a diode. Also, the variable resistance element RM may be formed of a magnetic tunnel junction (MTJ) element.

Example embodiments, describe the memory cell MC is a magnetic memory cell. However, the inventive concept is not limited thereto. For example, the resistive memory device may be a phase change random access memory where the variable resistance element RM may be formed of a phase change material (e.g., GST: Ge—Sb—Te). Alternatively, the resistive memory device may be a resistive random access memory where the variable resistance element RM may be formed of a material (e.g., complex metal oxide) having a variable resistance characteristic.

In FIG. 1, an access element of each memory cell MC may be connected with a word line and a variable resistance element RM of each memory cell MC may be connected with a bit line.

Memory cells MC may be disposed at intersections of word lines and bit lines to form a sub memory cell array. A memory bank may be formed of a plurality of sub memory cell arrays and a plurality of memory banks may constitute a memory cell array.

In FIG. 1, a part of the sub memory cell array in the memory cell array 300 may be illustrated.

At least one or more bit line sense amplifier 350 may be disposed at the sub memory cell array and connected in common with bit lines BL0, BL1, BL2, and BL3, belonging to different pages PG0, PG1, PG2, and PG3, from among bit lines. The bit line sense amplifier 350 may be connected with one of the shared bit lines BL0, BL1, BL2, and BL3 through selection switches 331 to 334 when a page is selected.

The row decoder 100 may perform a function of a page decoder, and may be often referred to as a first decoder. The row decoder 100 may generate a page selection signal that allows one of the shared bit lines BL0, BL1, BL2, and BL3 to be connected with the bit line sense amplifier 350. The fusion decoder 200 may perform a function of a mixed decoder in which a row decoding function and a column decoding function are mixed, and may be referred to as including a secondary decoder. The fusion decoder 200 may generate a word line selection signal for selecting one of word lines WL0, WL1, WL2, and WL3 and a sub block selection signal OSL0 for selectively connecting a sensing output terminal SA0 of the bit line sense amplifier 350 and an input/output line LIO or GIO.

A memory cell 10 may be accessed when the word line WL0 is selected by the fusion decoder 200 and the selection switch 331 is turned on by the row decoder 100.

At a read operation, since a page output terminal PG0 connected with the bit line BL0 is connected with an input terminal BLI, the bit line sense amplifier 350 may sense data stored at the memory cell 10. Data may be sensed by detecting whether a resistance state of the memory cell 10 is at a high-resistance state or a low-resistance state, based on a reference value. For example, the amount of current flowing through the memory cell 10 having a high-resistance state may be relatively less. The amount of current flowing through the memory cell 10 having a high-resistance state may be relatively more. In case of a single-level memory cell, data stored at the memory cell 10 may be determined to be ‘1’ or ‘0’ by detecting a variation of a current flow.

Data output from the sensing output terminal SA0 of the bit line sense amplifier 350 may be applied to a local sense amplifier 370. An output terminal LS0 of the local sense amplifier 370 may be connected with a global input/output line GIO when a column switch 380 is turned on. Thus, data output from the local sense amplifier 370 may be finally sensed and amplified by a global sense amplifier connected with the global input/output line GIO to be output to an external device through an input/output driver.

In FIG. 1, there is illustrated an example in which the column switch 380 switched by the fusion decoder 200 is connected with the output terminal LS0 of the local sense amplifier 370. However, the inventive concept is not limited thereto. For example, the column switch 380 may be installed between the bit line sense amplifier 350 and the local sense amplifier 370. In this case, data output from the sensing output terminal SA0 of the bit line sense amplifier 350 may be applied to the local sense amplifier 370 when the column switch 380 is turned on.

At a write operation (which is sometimes called a program operation) in which data is stored at the selected memory cell 10, the bit line sense amplifier 350 may take charge of a write driver circuit. At a write operation, the bit line sense amplifier 350 may supply the memory cell 10 with a write current for switching a magnetization direction of a memory cell according to write data.

As illustrated in FIG. 1, if the bit line sense amplifier 350 shares a plurality of bit lines, the number of bit line sense amplifiers installed within the memory cell array 300 may be minimized or reduced. Thus, a chip size of the resistive memory device may be reduced.

When word lines of the sub memory cell arrays in a memory bank are enabled and page open is executed, the bit line sense amplifier 350 may be independently enabled after a column address and a read command are received. The bit line sense amplifier 350 may sense data of a memory cell connected with a bit line selected by a page selection signal PGS. For example, at a read operation, if the word line WL3 is enabled and the switch transistor T1 is turned on by activation of a page selection signal PGS_A, the bit line sense amplifier 350 may sense data stored at the memory cell 10.

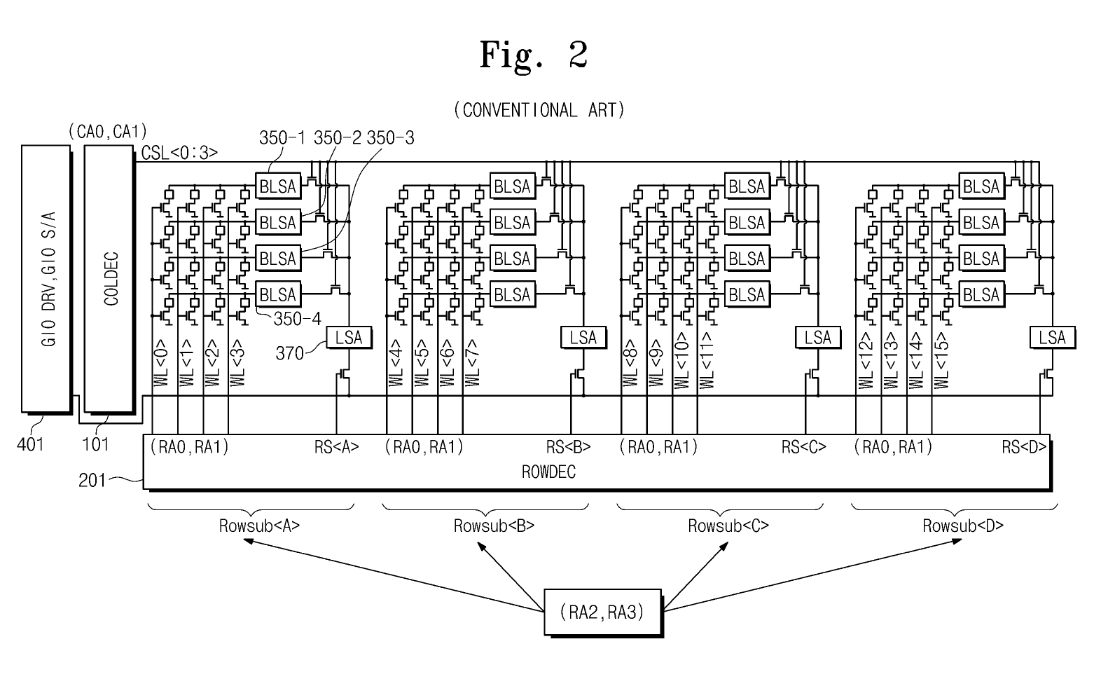

A sensing scheme according to an embodiment of the inventive concept may be distinguishable from that of FIG. 2 showing a bit line sense amplifier installed every bit line, that is, a typical sensing scheme in which data stored at all memory cells connected with a selected word line is sensed.

Referring to FIG. 1, a selective sensing operation on a selected memory cell may be implemented without sensing all memory cells connected with an activated word line at a page open mode of operation. Thus, it is possible to minimize or reduce power consumption at memory operations such as a read operation, a write operation, and so on.

FIG. 2 is a diagram schematically illustrating arrangement of a typical memory cell array.

Referring to FIG. 2, a memory cell array of a typical resistive memory device has a structure such that a bit line sense amplifier is provided for every bit line. A page open mode of operation may be executed at a structure of FIG. 2.

It is assumed that a resistive memory device or a DRAM is connected with a processor. The processor may support a page open policy to write data at the resistive memory device or DRAM or to read data from the resistive memory device or DRAM.

A data access speed at a page open policy may be faster than that at a page closed policy. For example, with the page open policy, in the event that data is read from memory cells connected with the same word line, a word line may be activated and selected bit lines may be activated one by one. With the page closed policy, the same word line may be iteratively activated at the time just before selected bit lines are activated. Thus, the page closed policy may need a time when an activated bit line is closed and the same word line is again activated. As a result, in case of the page open policy, since bit lines are selected at the same time with a selected word line being continuously activated, processors connected with a DRAM may mostly use the page open policy to improve an access speed to a memory.

In case of a structure illustrated in FIG. 2 or a DRAM having a page open mode of operation, a bit line sense amplifier BLSA may be disposed every bit line or every bit line pair. Therefore, a lot of a chip area may be occupied by the bit line sense amplifiers BLSA.

If a memory structure of FIG. 2 is implemented to allow a resistive memory device to perform the same page open operation as that of a DRAM, driver circuits (e.g., write drivers, etc.) other than the bit line sense amplifiers BLSA may be additionally formed. This may mean that a chip area occupied increases in comparison with that of a DRAM.

A 64-bit memory cell array in FIG. 2 may use a 4-bit row address and a 2-bit column address.

Since 16 word lines WL<0> to WL<15> are formed, 16 pages may exist. One of the 16 word lines WL<0> to WL<15> may be selected by decoding four row address signals RA0, RA1, RA2, and RA3. At a page open read operation, if a word line is enabled, four BLSAs in one of four row sub blocks (Rowsub<A>, Rowsub<B>, Rowsub<C> or Rowsub<D>) may be driven at the same time. Data simultaneously sensed by four BLSAs may be provided to a local sense amplifier LSA according to four column selection signals generated by decoding a 2-bit column address. For example, it is assumed that a row sub block Rowsub<A> is selected and data is simultaneously sensed by four BLSAs 350-1, 350-2, 350-3, and 350-4. With this assumption, when a first column selection signal CSL<0> is activated, sensed data output from the BLSA 350-1 may be transferred to the LSA 370. When a second column selection signal CSL<1> is activated, sensed data output from the BLSA 350-2 may be transferred to the LSA 370. When a third column selection signal CSL<2> is activated, sensed data output from the BLSA 350-3 may be transferred to the LSA 370. When a fourth column selection signal CSL<3> is activated, sensed data output from the BLSA 350-3 may be transferred to the LSA 370. An output of the LSA 370 may be transferred to a global sense amplifier 401 through a global input/output line when a row sub selection signal RS<A> is selected by decoding row address signals RA2 and RA3. The global sense amplifier 401 may be connected with an input/output circuit unit including an input/output driver, and output data of the global sense amplifier 401 may be read by an external device.

At a page open write operation, write data provided from the external device may be transferred to a BLSA, selected by CSL<0:3>, through the global sense amplifier 401 and the LSA 370. Data transferred to the selected BLSA may be written at a memory cell disposed at an intersection of a selected word line and a selected bit line.

In case of a structure of FIG. 2, at the page open mode of operation, four BLSAs may be used. On the other hand, since remaining 12 BLSAs are connected with unselected pages, they are not used. That is, if a page is opened in a 4-page memory structure, remaining pages, that is, 3 pages may be closed until they are selected to be opened. For this reason, the 12 BLSAs not connected to an open page are not be driven.

In the structure of FIG. 2, if a word line selected by row activation is enabled, four BLSAs may perform a data sensing operation at the same time. A constant current may be simultaneously applied to all selected memory cells to perform the data sensing operation at the same time. In this case, power noise may be generated. The power noise may be one of factors that causes a reduction of a sensing margin at a read operation.

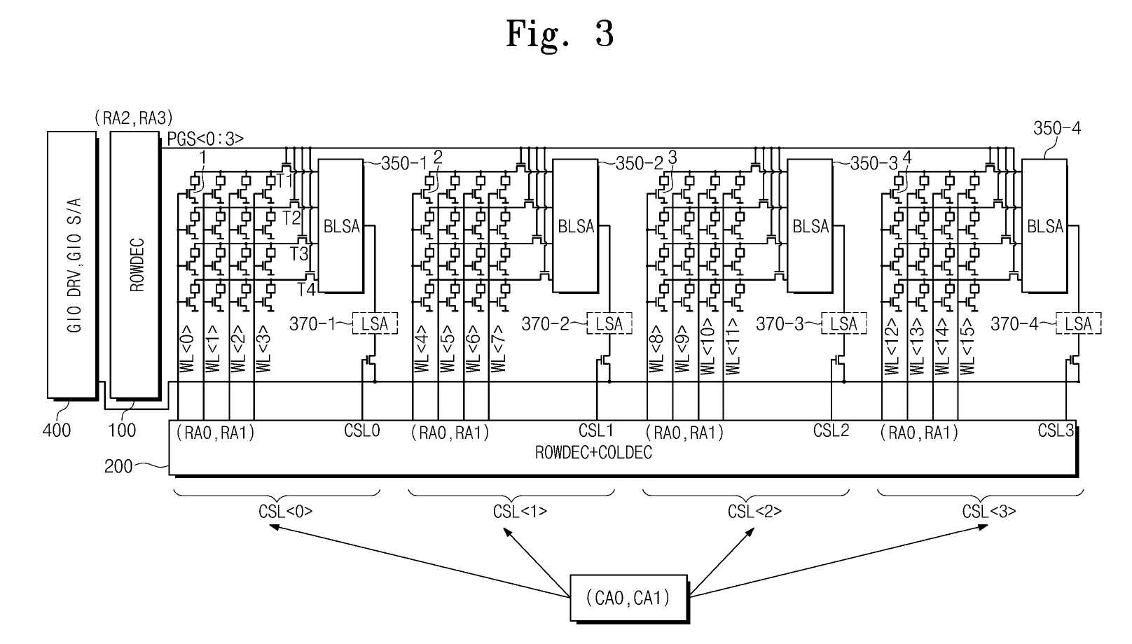

In example embodiments, a new memory structure of FIG. 3 may be provided based on a technical concepts of FIG. 1.

FIG. 3 is a block diagram schematically illustrating a memory cell array according to an embodiment of the inventive concept which may reduce or minimize chip size as compared to the memory cell array of FIG. 2.

Four BLSAs 350-1, 350-2, 350-3, and 350-4 may be disposed at a 4-bit page size to scale down a chip size in comparison with FIG. 2. A BLSA may be formed every row sub block (corresponding to a sub memory cell array of FIG. 1). That is, a BLSA may be necessary per page.

As described with reference to FIG. 1, to allow a structure of FIG. 3 to support a page open mode of operation, use of row and column addresses may be different from that of FIG. 2. In case of a structure of FIG. 2, four memory cells connected with the same word line form a page. On the other hand, in case of a structure of FIG. 3, memory cells belonging to the same page may be formed of memory cells 1, 2, 3, and 4.

One of the exemplary word line enable methods is to activate a word line in each of four row sub blocks at the same time when a row address is applied. For example, word lines WL0, WL4, WL8, and WL12 may be activated at the same time.

Another of the exemplary word line enable methods is be to sequentially activate word lines one by one after a column address is applied. This method may be used to reduce power consumption as compared to simultaneous activation. For example, a word line WL4 may be activated after a word line WL0 is activated. Afterwards, word lines WL8 and WL12 may be sequentially activated.

In the event that memory cell 1 is selected at a read mode of operation, BLSA 350-1 (of four BLSAs 350-1, 350-2, 350-3, and 350-4) is driven. Since a page selection signal PGS<A> is activated by decoding row address signals RS2 and RA3, switching transistor T1 is turned on. Thus, BLSA 350-1 may sense data stored in the memory cell 1. Since remaining switching transistors T2 to T4 are turned off, data stored at remaining memory cells of four memory cells connected with a word line WL<0> other than the memory cell 1 may not be sensed by the BLSA 350-1.

As described above, a sensing scheme of FIG. 3 may be a selective page sensing scheme to selectively sense data stored of a memory cell connected with a selected word line, not an all page sensing scheme for sensing data of all of the memory cells connected with the selected word line.

If a sub block selection signal OSL0 is enabled by a decoding operation of a second decoder 200, data sensed through the BLSA 350-1 may be transferred to a GIO S/A 400 through LSA 370-1 and a GIO line.

Referring to FIGS. 2 and 3, a column decoder 101 of FIG. 2 may be replaced with a row decoder 100 of FIG. 3, and a row decoder 201 of FIG. 2 may be replaced with the fusion decoder 200 of FIG. 3.

In FIG. 3, two row address signals RA0 and RA1 of a four-bit row address RA0, RA1, RA2, and RA3 may be used to select one of four word lines in each row sub block, and two row address signals RA2 and RA3 may be used to generate selection signals PGS<A:D> for selecting one of four row sub blocks. Since one of four pages is selected by the selection signals PGS<A:D>, the selection signals PGS<A:D> may function as a page selection signal.

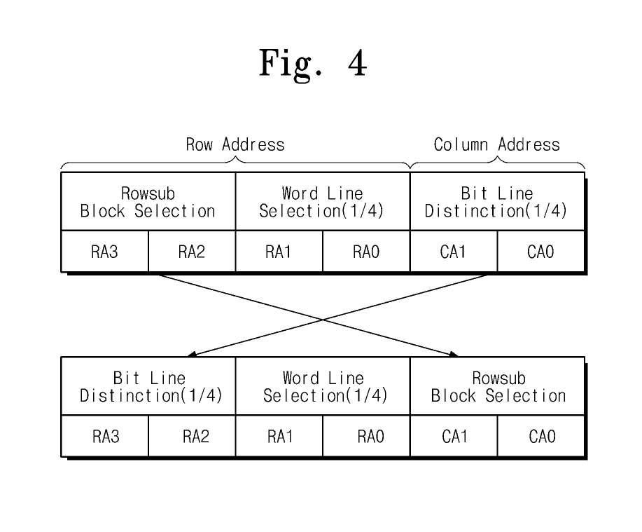

FIG. 4 is a comparison table of address use associated with operations of FIGS. 2 and 3, with the upper portion of FIG. 4 representing operations of FIG. 2 and the lower portion of FIG. 4 representing operations of FIG. 3. In case of FIG. 2, a column address may be used to select a bit line (for bit line distinction). On the other hand, in case of FIG. 3, a row address RA2 and RA3 may be used to select a bit line (for bit line distinction). In case of FIG. 2, a row address RA2 and RA3 may be used to select a row sub block. On the other hand, in case of FIG. 3, a column address CA0 and CA1 may be used to select a row sub block. In case of FIGS. 2 and 3, a row address RA0 and RA1 may be used to select word lines.

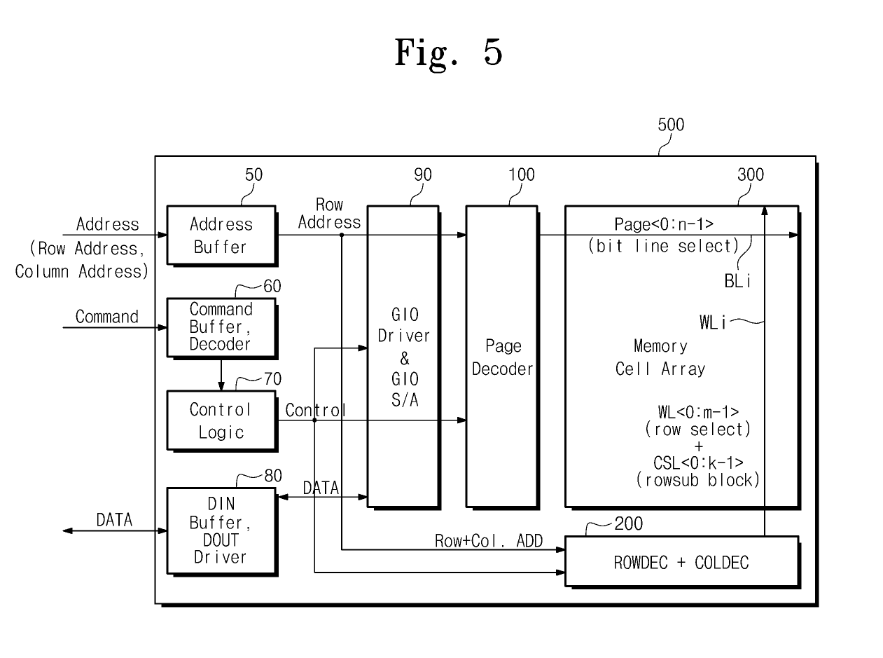

FIG. 5 is a block diagram schematically illustrating a resistive memory device including a memory cell array of FIG. 1. A memory cell array 300 of FIG. 5 may have such a memory structure as described with reference to FIG. 3.

Referring to FIG. 5, a resistive memory device 500 may include an address buffer 50, a command buffer and decoder block 60, control logic 70, a data input buffer and output driver block 80, a global input/output driver and global input/output sense amplifier block 90, a page decoder 90, a fusion decoder 200, and a memory cell array 300.

The address buffer 50 may receive and buffer a row address and a column address applied from a processor or a memory controller.

The command buffer and decoder block 60 may buffer and decode a command (e.g., a read command or a write command) applied from the processor or the memory controller.

The control logic 70 may generate various control signals needed for a memory access operation according to the decoded command.

The data input buffer and output driver block 80 may be used to input write data or output read data, and may generally control input/output circuit operations.

The global input/output driver and global input/output sense amplifier block 90 may send write data to a global input/output line or finally sense and amplify read data transferred to the global input/output line to provide the sensed and amplified data to the data input buffer and output driver block 80.

The page decoder 100 and the fusion decoder 200 may respectively comprise a primary decoder function and a secondary decoder function as described with reference to FIG. 1. The page decoder 100 may decode a row address. The fusion decoder 200 may decode both a row address and a column address.

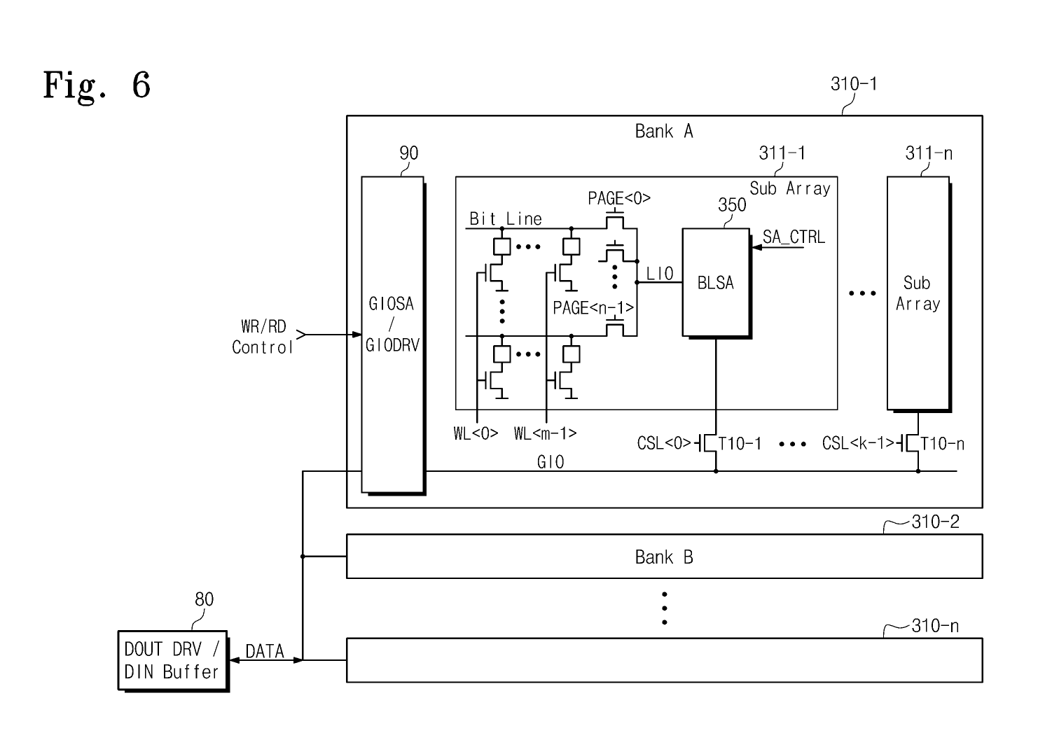

The memory cell array 300 may include a plurality of memory banks (e.g., 310-1 of FIG. 6) each including a plurality of sub memory cell arrays (corresponding to a row sub block) in which magnetic memory cells are arranged at intersections of word lines WLi and bit lines BLi. In the event that the bit lines BLi (i being a natural number of 2 or more) are formed of bit lines <0:n−1> (n being a natural number of 3 or more). The word lines WLi may be formed of word lines <0:m−1> (m being a natural number of 4 or more). If the number of row sub blocks is (k−1) (k being a natural number of 1 or more), CSL<0:k−1> may be used.

FIG. 6 is a diagram illustrating a memory bank structure of a memory cell array of FIG. 5 and a data input/output path.

Referring to FIG. 6, a plurality of memory banks 310-1 to 310-n may form a memory cell array 300, and may be connected with a data input buffer and output driver block 80.

A memory bank 310-1 may include a plurality of sub memory cell arrays 311-1 to 311-n.

In a sub memory cell array 311-1, a bit line may be connected with m memory cells (m being a natural number of 4 or more). Each memory cell may be selected by activation of m word lines WL<0:m−1> and n page selection switches PAGE<0:n−1>.

Bit lines may be connected with BLSA 350 through the page selection switches PAGE<0:n−1>, respectively. The BLSA 350 may be shared by n bit lines. Herein, each of the n bit lines may correspond to different pages.

Selection of m word lines and selection of n pages may be made by decoding a row address applied at a page open mode of operation.

A BLSA (e.g., 350) formed every sub memory cell array (e.g., 311-1) and an input/output line may be connected by activating one of k CSL signals CSL<0:k−1>. At this time, the signals CSL<0:k−1> may be generated by decoding a column address applied when a command is received.

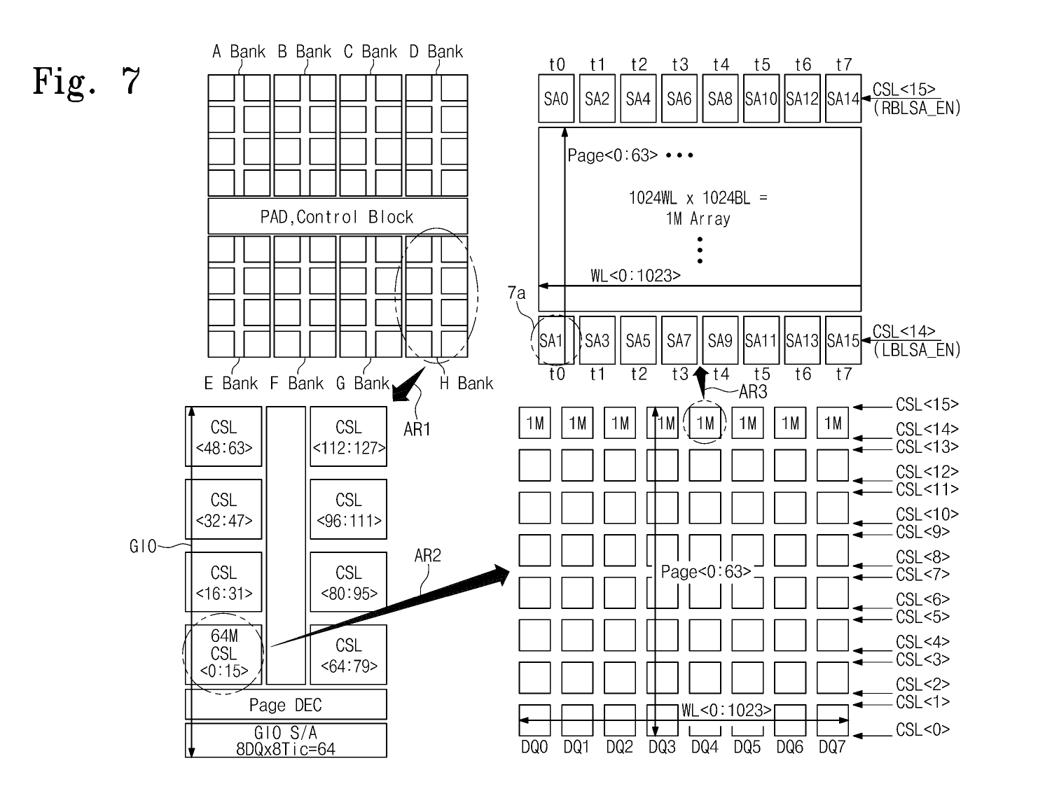

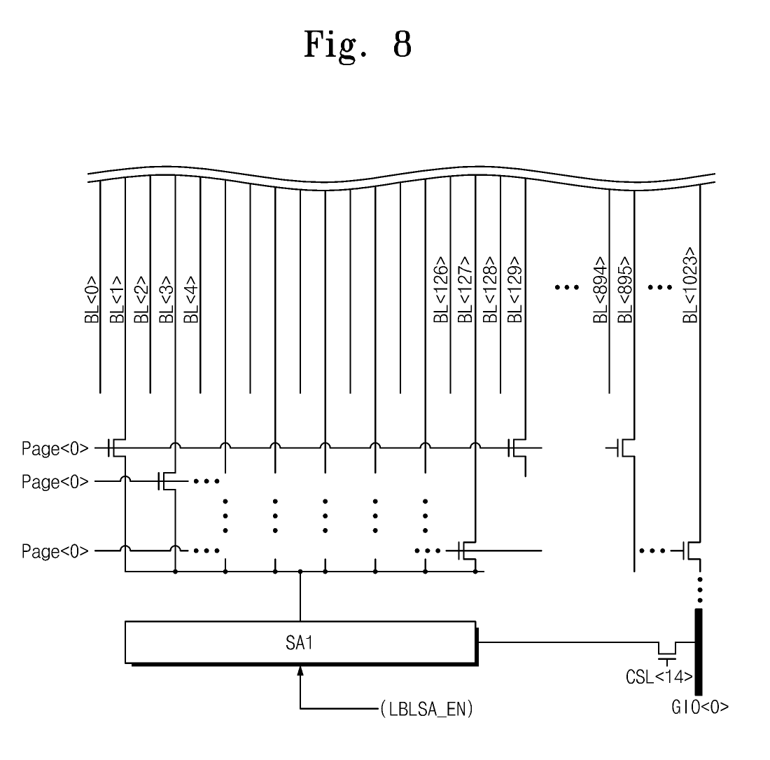

FIG. 7 is a diagram schematically illustrating a full chip structure according to an embodiment of the inventive concept. FIG. 8 is a detailed diagram of a sense amplifier area of FIG. 7.

Referring to FIG. 7, a 4G-bit memory chip comprises eight memory banks A to H. While the memory chip in FIG. 7 has an 8k-bit page size, the inventive concept is not limited thereto.

8k BLSAs may be evenly distributed within a full chip to implement an 8k-bit page size.

In the example of FIG. 7, there are 8 banks, CSL<0:127>, WL<0:1024>, PAGE<0:63>, and 16BLSA@1M(Mega bit). Thus, since density=4G, 8DQ, and 8Tic, a page may have a size of 8k bits (128×8×8).

Word lines WL<0:1023> may be selected by decoding a 10-bit row address. Pages PAGE<0:63> may be selected by decoding a 6-bit row address. Column selection lines CSL<0:127> may be selected by decoding a 7-bit column address.

Referring to arrow AR1 in FIG. 7, one memory bank (e.g., H bank) may be formed of 512 1 M-memory cell arrays. A word line WL may be enabled all over 8 8M-memory cell arrays. 128 column selection lines for selecting bit lines may be used to select 64 8M-memory cell arrays at each of right and left sides as illustrated by arrow AR2.

Eight BLSAs may be disposed at the right side of a 1M-memory cell array (SA0, SA2, . . . SA14) and eight BLSAs may be disposed at the left side of the 1M-memory cell array (SA1, SA3, . . . SA15) as highlighted by arrow AR3. Each BLSA may be shared by 64 pages of bit lines as illustrated in FIG. 8.

Memory cells may be simultaneously accessed such that eight bits of data are output from eight BLSAs at one of the left and right sides of a 1 M-memory cell array.

If a word line is enabled, eight 1M-memory cell arrays of an 8M-memory cell array may be accessed at the same time, and each 1 M-memory cell array may be designed to have eight DQs.

When a read command or a write command is received, 64 BLSAs may operate at the same time, and 64 BLSAs of 8k BLSAs may be selected using a column address.

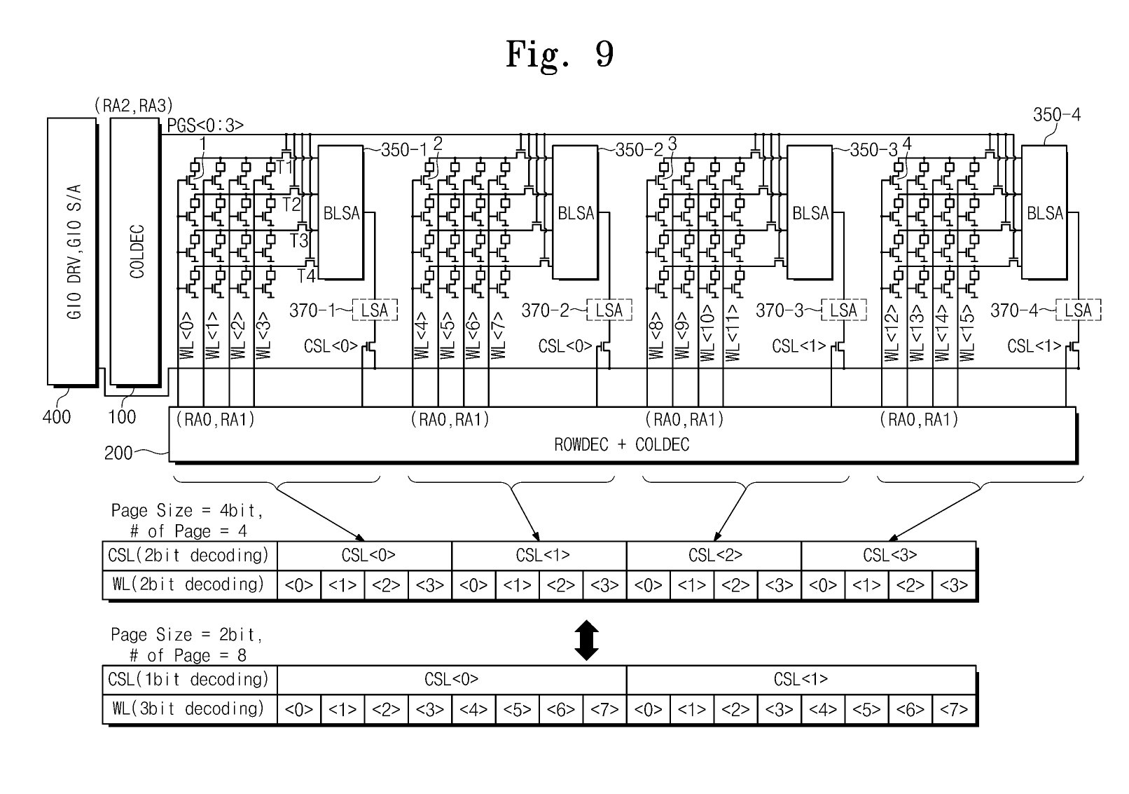

FIG. 9 is a diagram for describing an example in which a page size of a memory cell array, such as that of FIG. 3, may be changed.

In FIG. 9, a page size (e.g., a page-per-bit number) may be changed as occasion demands by changing the number of column address bits and the number of row address bits. In other words, the number of memory cells connected with a page may vary by adjusting the number of address bits.

For example, it is assumed that a page size is N (N being a natural number of 2 or more) when all BLSAs in a bank operate at a page open operation. As the number of row address bits increases by 1 and the number of column address bits decreases by 1, the number of column selection lines may be halved and the number of word lines may be doubled. In this case, a page size may be halved. That is, a page size may be changed from N to N/2.

A memory of FIG. 3 having four column selection lines CSL<0:3> and a 4-bit page size may be changed to a memory having two column selection lines CSL<0:1> and a 2-bit page size by changing the number of row address bits and the number of column address bits. In FIG. 9, in the event that a 4-bit page size is changed to a 2-bit page size, a decoding bit number for column selection lines may be changed from 2 to 1 and the number of row address bits may be changed from 2 to 3.

Thus, a page size may be easily changed by changing address coding. Herein, a page size may be changed on the fly by using a mode register set (MRS) code or a separate command.

If an address is received, a bit of a bank address may be used as a column address. Thus, the number of memory banks may decrease and a page size may increase. In this case, a part of bank address bits received with a row address may be “don't cared”.

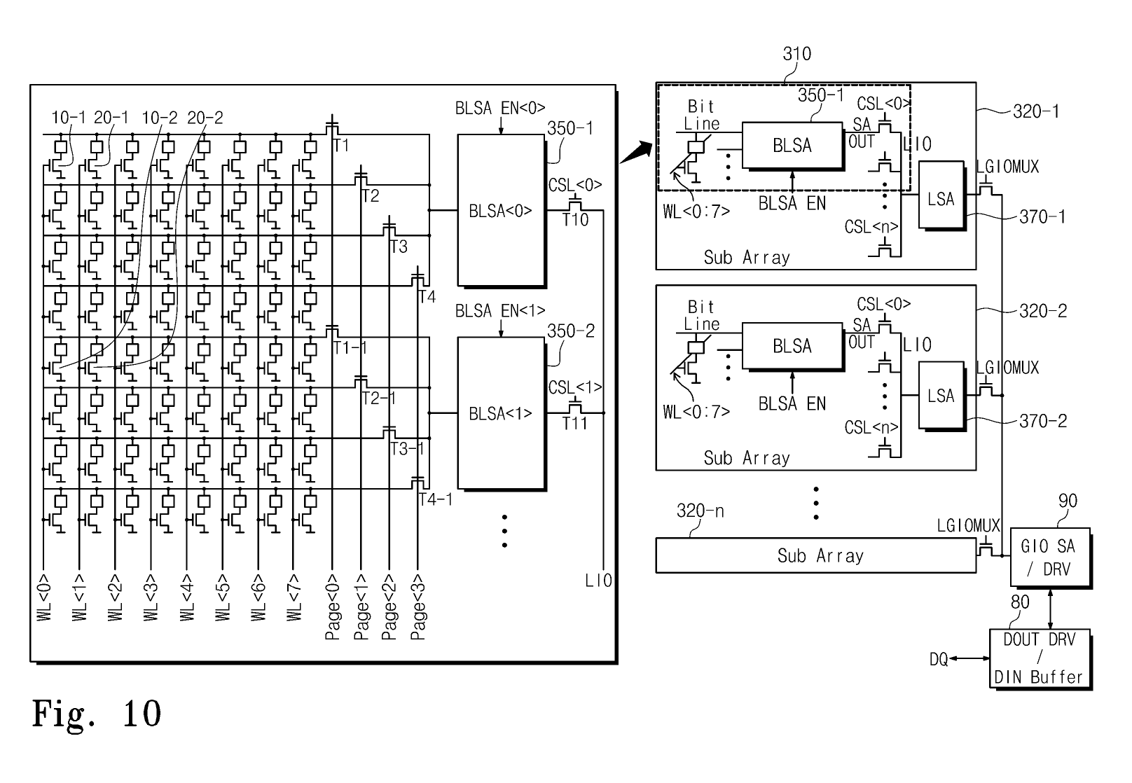

FIG. 10 is a block diagram schematically illustrating a memory cell array according to another embodiment of the inventive concept.

Referring to FIG. 10, there may be illustrated such a structure that a sub memory cell array includes 64 memory cells and two BLSAs 350-1 and 350-2 are disposed per sub memory cell array.

An upper BLSA 350-1 may be connected with one of four upper bit lines of eight bit lines when one of upper page selection switches T1 to T4 is turned on. A lower BLSA 350-2 may be connected with one of four lower bit lines of the eight bit lines when one of lower page selection switches T1-1 to T4-1 is turned on.

Sensing outputs of the BLSAs 350-1 and 350-2 may be selected by column selection lines CSL<0> and CSL<1> generated by decoding a column address bit, and the sensing output selected may be provided to a logical input/output line LIO.

In FIG. 10, activation of one of word lines WL<0:7> and one of selection signals PAGE<0:3> allows access to memory cells of one of the 32 different pages.

One of outputs of BLSAs may be selected by CSL<0:n> such that it is connected with LSA through a logical input/output line. Data output from one of a plurality of LSAs may be transferred to a global input/output line GIO by a selection operation of LGIOMUX.

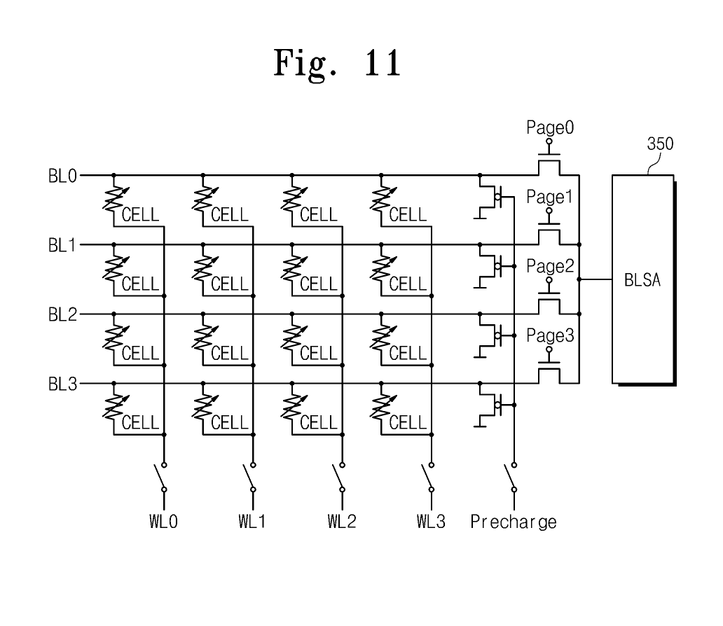

FIG. 11 is a diagram schematically illustrating connection between a shared bit line sense amplifier 350 and a sub memory cell array having a cross-point arrangement structure.

As illustrated in FIG. 11, a bit line sense amplifier 350 shared by bit lines BL0 to BL3 belonging to different pages may be applied to a cross point type memory cell array structure in which memory cells formed of a resistive element without an access element are connected at intersections of word lines and bit lines. The architecture described in FIG. 1 may be applied to FIG. 11.

Four bit lines BL0 to BL3 may be selected by four page selection signals Page0 to Page3 to be connected with a shared BLSA 350. Four word lines WL0 to WL3 may be selected by decoding of a row address. In FIG. 11, pre-charge transistors for pre-charging bit lines in response to a pre-charge signal Precharge may be illustrated. In some embodiments, the pre-charge transistors may be removed.

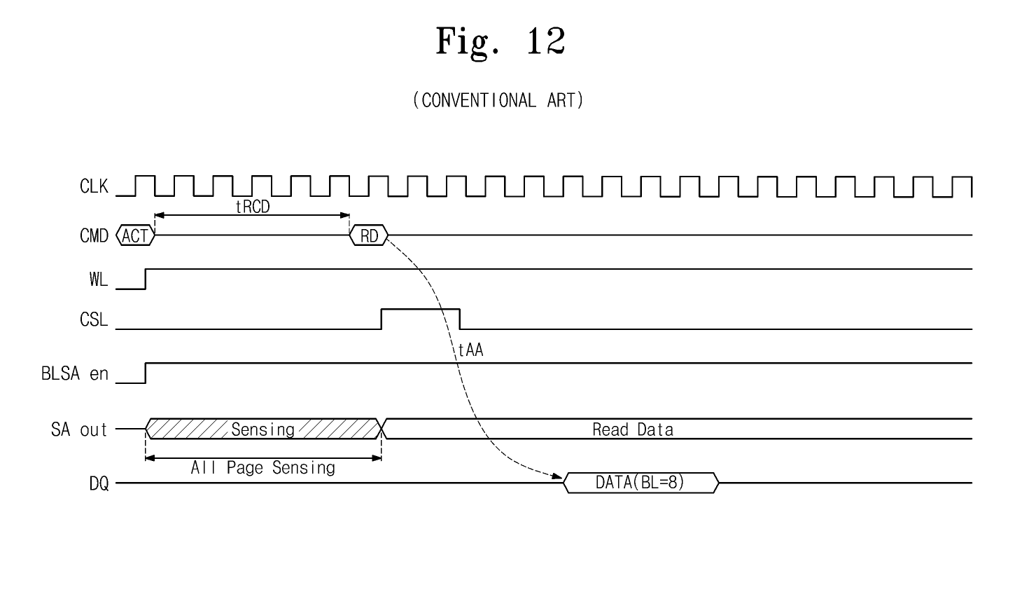

FIG. 12 is a read operation timing diagram according to the typical device shown in FIG. 2.

If an active command for activating a word line at execution of a page open mode of operation is received, data stored at all memory cells in an opened page may be sensed at the same time. In FIG. 12, reference marks CLK, WL, CSL, BLSA en, SA out, and DQ may indicate a clock signal, a word line enable signal, a column selection line signal, a BLSA enable signal, a BLSA output signal, and read data, respectively.

During tRCD, there may be performed an all page sensing operation in which data stored at all memory cells connected with a selected word line is sensed at the same time.

At the all page sensing operation, it is necessary to drive BLSAs connected with bit lines at the same time. For this reason, a lot of power may be consumed. In case of a page open operation, all data of the opened page may always be required.

For example, for both a full page access and 1-bit data access of a page open mode of operation, a full page of data is sensed. For this reason, in case of the 1-bit data access, unnecessary data may be sensed. Thus, power loss may be generated.

In a resistive memory device, a constant current may be applied to all memory cells selected at the all page sensing operation. For this reason, if unnecessary data is sensed, considerable power loss may be generated in comparison with a DRAM. Also, if a current is supplied to all memory cells in an opened page at the same time, a power noise issue may be generated. In the event that power noise is serious, sensing margin may be reduced at a read operation.

In case of a DRAM, a word line may be activated and all memory cells connected with the activated word line may lose data stored therein. Thus, it is necessary to sense and latch data stored at memory cells through bit line sense amplifiers. On the other hand, in case of a resistive memory device, although a word line is activated, cell data may be retained. The reason may be that a resistive memory cell is a nonvolatile memory cell. Therefore, it is not necessary to sense all cell data.

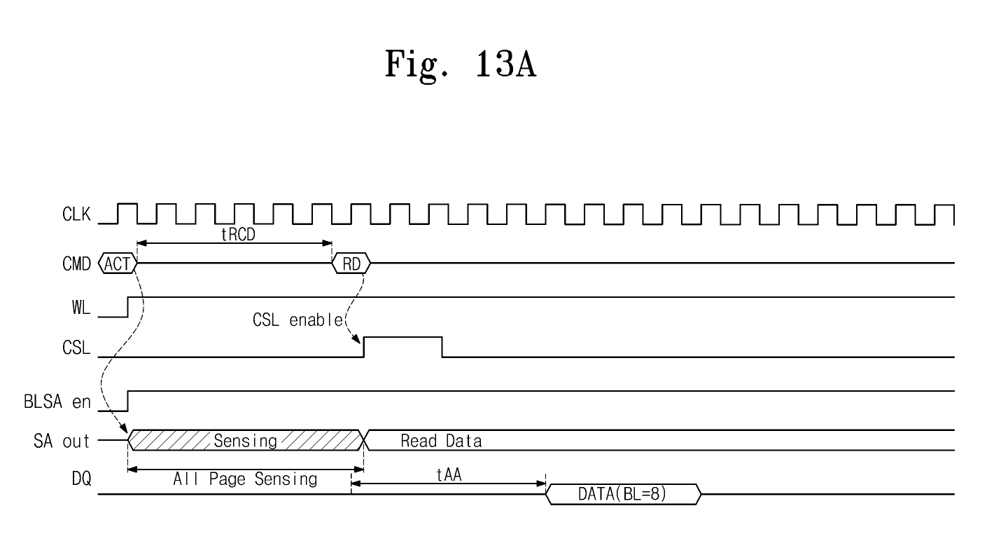

With an embodiment of the inventive concept, at a page open mode of operation, only necessary data may be selectively sensed when a read command is applied as illustrated in FIG. 13B, without simultaneous sensing of all cell data in a page.

Power consumption may be minimized or reduced by performing a selective sensing operation without sensing of unnecessary cell data. Also, it is possible to reduce or remove an issue of sensing margin reduction due to power noise.

In FIG. 13B, since a sensing operation is performed after an input of a read command, tAA may increase in comparison with a DRAM. tRCD may be substantially meaningless.

FIG. 13B is a read operation timing diagram that may reflect the operation of the devices of FIG. 1, 3, or 5. FIG. 13A shows the contrast between a read operation of the typical device of FIG. 2 (also represented by the timing of FIG. 12) and a read operation timing of FIG. 13B.

In case of the timing shown in FIG. 13B, if an active command for activating a word line is applied, an all page sensing operation for sensing all cell data in a page at the same time may be executed within a period of time tRCD. After the period of time tRCD elapses, a column selection line CSL may be activated according to an input of a read command. Data sensed by bit line sense amplifiers may be output as read data after a column address access time tAA.

In example embodiments, the active command may be the first command, and the read command may be the second command.

FIG. 13B shows exemplary read operation timing according to the devices of FIG. 1, 3 or 5.

Referring to FIG. 13B, at least one of a plurality of word lines may be activated in response to an active command ACT.

After a read command RD is received, data stored in memory cells corresponding to a selected page from among memory cells connected with the activated word line may be sensed through a bit line sense amplifier. The sensed data may be output as read data according to a sensing output control signal. In FIG. 13B, data DQ may be output as read data after tAA.

In the example of FIG. 13B, tAA may increase by a sensing delay and tRCD may be greatly decreased as compared to the timing shown in FIG. 13A. Meanwhile, it is possible to perform a tCCD cycle of read and write operations. Herein, tRCD indicates a RAS to CAS delay time and tCCD may indicate column address to column address delay.

A first time from an input of the first command until an input of the second command may correspond to tCCD. A second time from an input of the second command until an output of read data may correspond to tAA. In example embodiments, the first time may be shorter than the second time.

Unlike the case that all cell data in a page is simultaneously sensed at an active command, a sensing method in which only a portion of data (such as just necessary data) is sensed at an input of a read command may be advantageous to prevent or minimize sensing margin reduction due to power noise at a page open mode of operation.

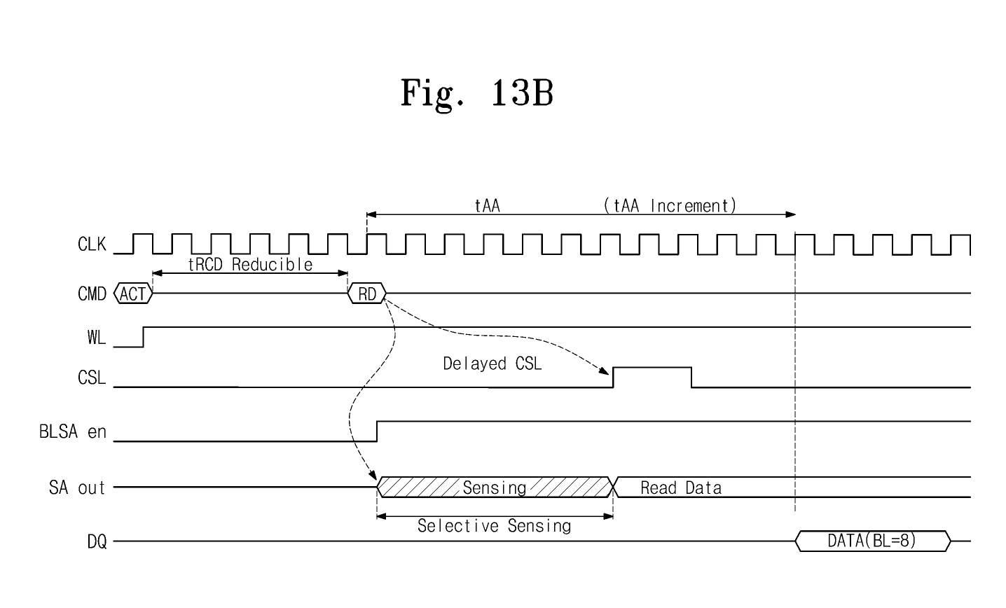

FIGS. 14A-C are used to show exemplary modifications of the read operation timing diagram of FIG. 13B.

FIG. 14A shows the timing of FIG. 13B. Since sensing of cell data starts after an input of a read command RD, tAA may relatively increases with respect to FIG. 13A. However, tRCD may be substantially unnecessary.

As shown in FIG. 14B, if a read command is applied immediately following an active command, a sensing period may be occur earlier in time. In FIG. 14B, tRCD may be set to one clock. Thus, it is possible to compensate for an increase in latency due to an increase in tAA by reducing tRCD.

In FIG. 14C, since a sensing operation is performed after an input of a read command, a word line enable timing may be shifted until a read command is received. Thus, such timing change may enable only a selected word line to be activated without simultaneous activation of all word lines connected with memory cells in the same page. That is, it is possible to selectively enable only a necessary word line according to a read command RD. Thus, if the timing of the FIG. 14C is applied to FIG. 1 or 3, power consumption and power noise may be reduced or minimized at a read operation.

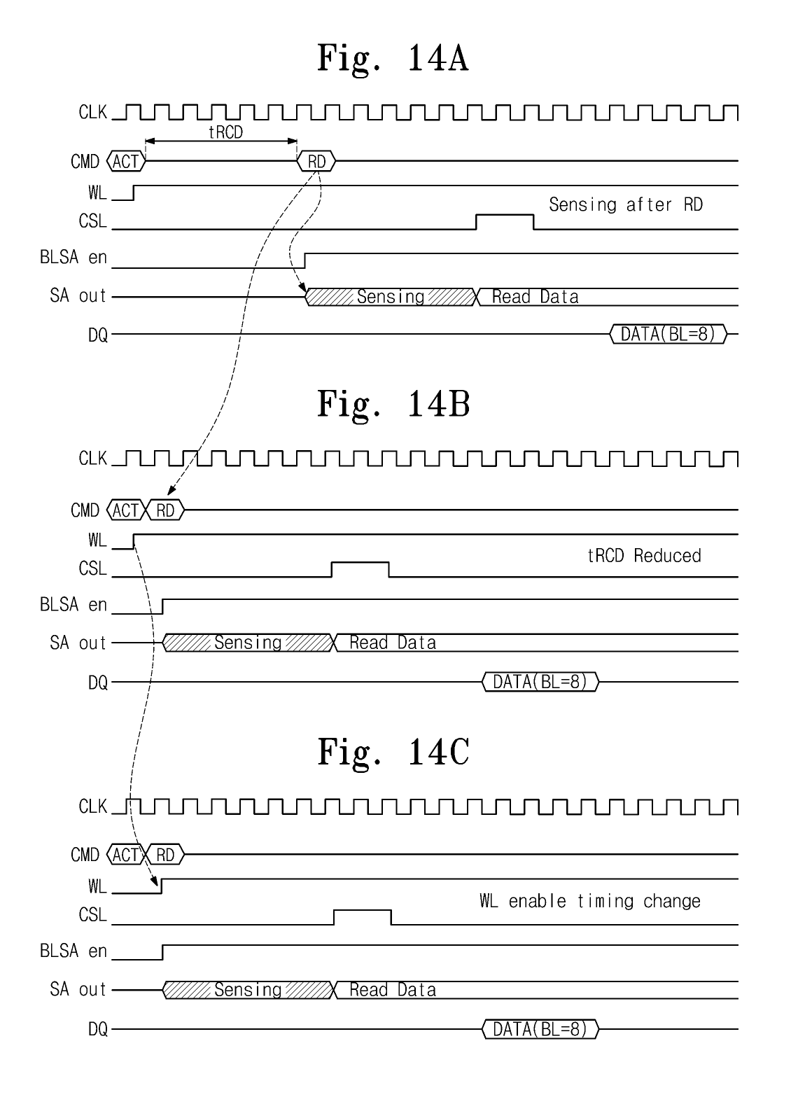

FIG. 15 is a write operation timing diagram according to FIG. 1, 3 or 5.

Referring to FIG. 15, one of a plurality of word lines may be activated in response to an active command ACT. If a write command following the active command is received, a column selection control signal CSL and a bit line enable signal BLSA en may be activated at t10 in response to a completion of an input of write data DQ.

If a bit line sense amplifier BLSA is driven by the activated bit line enable signal, the write data DQ may be stored in memory cells, corresponding to a selected page, from among all memory cells connected with the activated word line.

In the exemplary write operation of FIG. 15, the column selection control signal CSL is activated as soon as possible for a high-speed write operation.

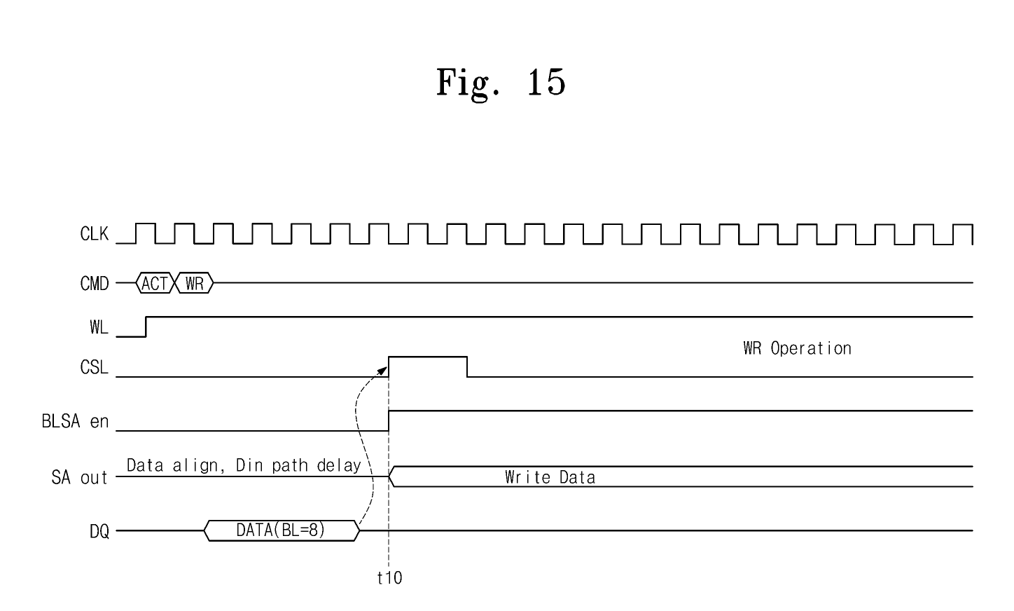

FIG. 16 is a tCCD sequential read operation timing diagram according to FIG. 1, 3 or 5.

FIG. 16 illustrates an example in which a read command RD is sequentially received every tCCD interval.

Arrow AR10 indicates when a sensing operation of a sense amplifier SA<0> is completed in response to a read command RD<0>.

Arrow AR11 indicates when a sensing operation of a sense amplifier SA<1> is completed in response to a read command RD<1>.

Arrow AR12 indicates when a sensing operation of a sense amplifier SA<2> is completed in response to a read command RD<2>.

Herein, it is assumed that tCCD is set to 4 clocks for a page open mode of operation.

In the event that three read command RD are continuously received after an active command is received (after a word line is enabled), cell data corresponding to each read command may be sequentially sensed by a corresponding BLSA. As illustrated by arrows AR20, AR21, and AR22, sensed cell data may be sequentially read out to an external device.

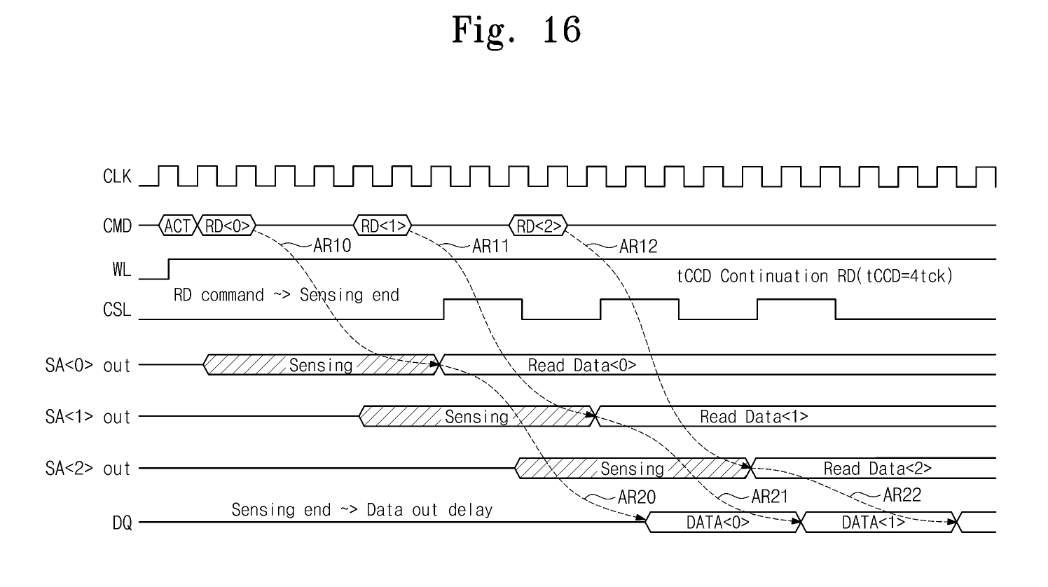

FIG. 17 is an operating timing diagram showing an exemplary a read control operation and a write control operation which may be used with the resistive memory device of FIG. 5.

In the event that a write command WR is received, a corresponding CSL may be enabled as soon as possible with a word line enable for a high-speed write operation. If the CSL is enabled, write data on the CSL may be directly written to a memory cell through a corresponding BLSA. The period of time T10 indicates a switching time of a memory cell to alter data of the memory cell.

Meanwhile, if a read command RD is received, a CSL may be enabled after a point of time when sensing of cell data through a corresponding BLSA is finished, as discussed elsewhere herein. That is, at a read operation, it is necessary to secure sensing delay by a period of time T20. When the CSL is enabled, sensing data on the CSL may be read out to an external device.

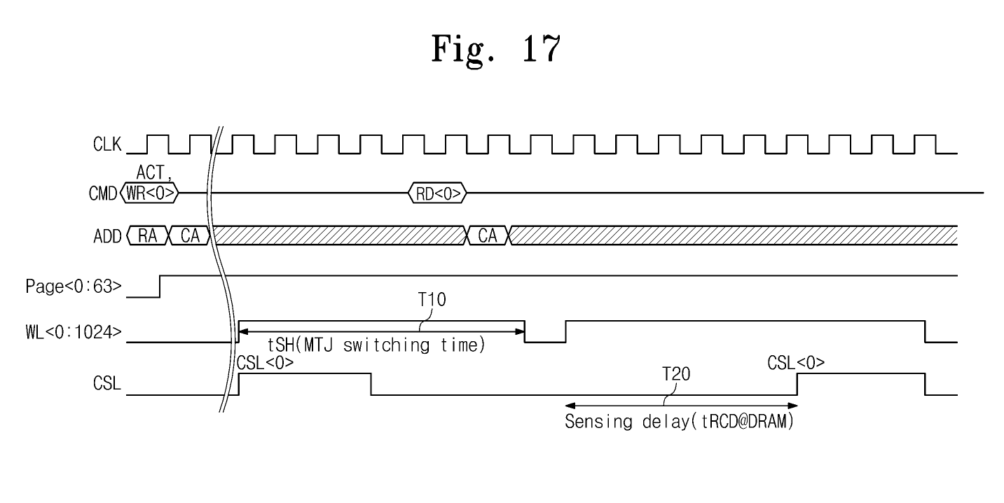

FIG. 18 is a diagram illustrating an operating principle of a memory cell applicable to the inventive concept.

An MRAM may be a memory using such a characteristic that a spin is divided into up and down. That is, the MRAM may be a nonvolatile memory technique using magnetic characteristics. For example, STT-MRAM may use electrons spin-polarized when the electrons penetrate a thin film (e.g., a spin filter). Also, the STT-MRAM may be divided into an STT-RAM, a spin momentum transfer RAM (SMT-RAM), and a spin transfer torque magnetization switching RAM (Spin-RAM).

A typical MRAM using a magneto-resistance effect for changing resistance of a conductive material using a magnetic field may include a plurality of resistance memory cells formed by MTJ (Magnetic Tunnel Junction).

A tunneling current (or, tunneling resistance) flowing through the MTJ may vary according to a magnetization state of a ferromagnetic material. The ferromagnetic material may include a free layer and a pinned layer with the MTJ interposed between the free layer and the pinned layer. The tunneling resistance may be low when magnetization directions of the free and pinned layers are parallel and high when magnetization directions of the free and pinned layers are anti-parallel. In the event that an anti-ferromagnetic layer called a pinning layer is added to the pinned layer, a magnetization direction of the pinned layer may be fixed and the tunneling resistance may vary according to a magnetization direction of the free layer. Herein, the magnetization direction of the free layer may be switched using a magnetic field formed by currents flowing along a bit line and a word line. In the above-described method, as a resistive memory device is highly integrated, a coercive force of the free layer may increase. This may cause unwanted switching of the free layer. Thus, there may be a growing interest in a magnetic memory device using a spin transfer torque manner or a magnetic memory device using a toggle switching writing manner.

The magnetic memory device using a spin transfer torque manner may switch a free layer in a required direction using a spin transfer of electron by providing a current in a direction where a spin is polarized. This may mean that the amount of current required is relatively reduced according to scale-down of a cell size. Thus, it is possible to integrate the resistive memory device highly.

A word line and a bit line may be disposed to be inclined by a 45° direction at an intersection, and an MTJ element may include a second magnetic area, a tunneling barrier, and a first magnetic area which are sequentially stacked. Herein, the first and second magnetic areas may include an SAF (Synthetic Anti-Ferromagnetic) structure which includes an upper ferromagnetic layer, a lower ferromagnetic layer, and a diamagnetic coupling spacer layer inserted between the upper ferromagnetic layer and the lower ferromagnetic layer.

Referring to FIG. 18, an STT-MRAM cell may include a magnetic tunnel junction (MTJ) element 105, a transistor 110, a bit line 120, and a word line 130. For example, the MTJ element 105 may be formed of a pinned layer and a free layer separated by an insulation (tunnel barrier) layer and each having a magnetic field. A source line 140 may be connected with the transistor 110 for a cell access through a line 114.

A sense amplifier 150 may compare a signal level of a bit line reference 170 and a signal level of a bit line 120 to amplify a comparison result (i.e., a difference between signal levels).

The MTJ element 105 may be grown on a metal layer known as a bottom electrode (BE) plate 180, and the bottom electrode plate 180 may be connected to an upper portion 112 of the transistor 110 through a seed (not shown). Mechanical surface characteristics (e.g., flatness or roughness) of the bottom electrode plate 180 may influence the performance of the MTJ element 105. The bottom electrode plate 180 may be formed of stiff polished metal, for example, a titanium alloy having mechanical characteristics suitable to form it on the MTJ element 105 or metal similar thereto.

In case of the MTJ element 105 having a low-resistance (RP) state, if a write current flows to the free layer from the pinned layer, a magnetization direction of the free layer may be switched. In this case, a state of the MTJ element 105 may be changed from the low-resistance (RP) state to a high-resistance (RAP) state. It is assumed that the case that a state of the MTJ element 105 is switched to the high-resistance state from the low-resistance state is referred to as “reset” and data ‘1’ is stored at a memory cell. In the reference symbol RP, “R” may indicate resistance and “P” may indicate parallel.

In case of the MTJ element 105 having the high-resistance (RAP) state, if a write current flows to the pinned layer from the free layer, a magnetization direction of the free layer may be switched. In this case, a state of the MTJ element 105 may be changed to the low-resistance state from the high-resistance state. It is assumed that the case that a state of the MTJ element 105 is switched to the low-resistance state from the high-resistance state is referred to as “set” and data ‘0’ is stored at a memory cell. In the reference symbol RAP, “R” may indicate resistance and “AP” may indicate anti-parallel.

A write operation of a resistive memory device may include a reset operation and a set operation, and may be referred to as a program operation as occasion demands.

At a read operation where the MTJ element 105 having a low-resistance (RP) state is read, a read current may flow to the free layer from the pinned layer. That is, likewise, a read current may easily flow in a direction A1, and the MTJ element 105 may be sensed by a sense amplifier to have the RP state. In this case, data ‘1’ is read.

At a read operation where the MTJ element 105 having a high-resistance (RAP) state is read, a read current may flow to the free layer from the pinned layer. Although a read current flows in the direction A1 at a read operation where a memory cell having a high-resistance (RAP) state is read, a read current may not easily flow in the direction A1. The MTJ element 105 may be sensed by a sense amplifier to have the RAP state. In this case, data ‘0’ is read.

A resistive memory device may include a voltage generating circuit. The voltage generating circuit may generate a read voltage when at a read operation where data is read from a memory cell and a write voltage at a write operation where data is stored at the memory cell.

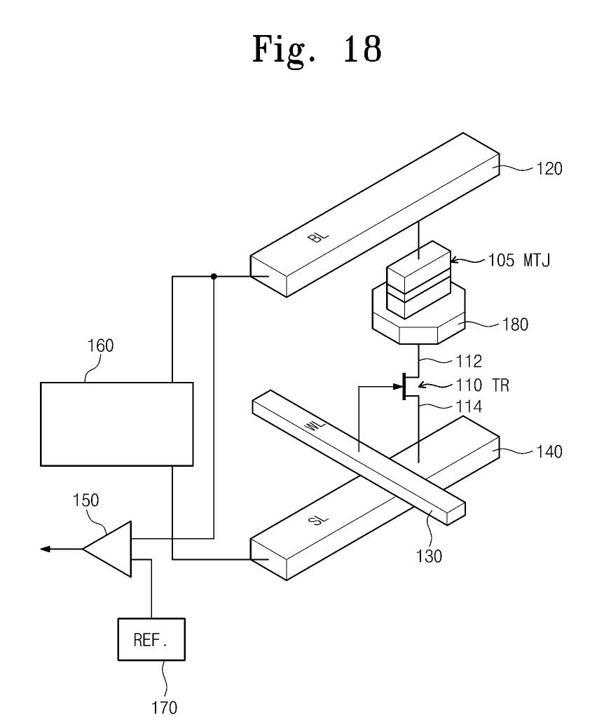

FIG. 19 is an equivalent circuit diagram of a memory cell of FIG. 18.

Referring to FIG. 19, an STT-MRAM cell may include a word line WL connected with an access transistor 510. A data storage element (e.g., MTJ element) 520 may be expressed by a resistor. The access transistor 510 and the MTJ element 520 in FIG. 19 may correspond to a transistor 110 and an MTJ element 105 in FIG. 18, respectively. The access transistor 510 and MTJ element 520 may be disposed between a bit line BL and a source line SL.

During a writing operation, a state “0” may be stored under the condition that WL=H, BL=H, and SL=L, and a state “1” may be stored under the condition that WL=H, BL=L, and SL=L. In example embodiments, “H” may be a high voltage/logic level, and “L” may be a low voltage/logic level. Voltage levels may be supply voltage levels (e.g., Vdd and 0V) or higher or lower than the supply voltage levels. The arrangement and state conditions may be exemplary. However, the inventive concept is not limited thereto.

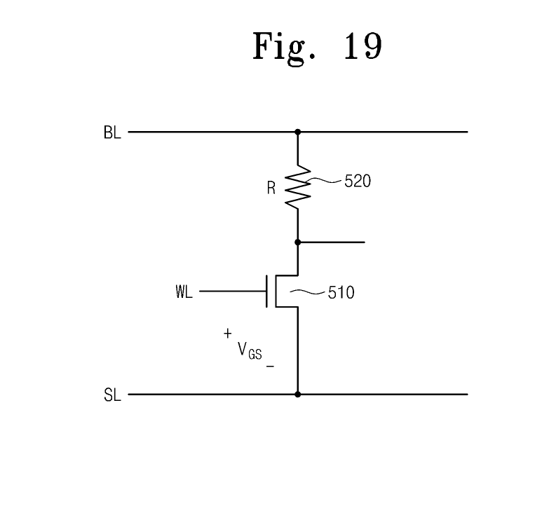

FIG. 20 is a block diagram schematically illustrating a mobile device according to the inventive concept.

Referring to FIG. 20, a mobile device (e.g., a smart phone) may include a multi-port MRAM 110, a first processor 210, a second processor 310, a display unit 410, a user interface 510, a camera unit 600, and a modem 700.

The multi-port MRAM 110 may include three ports connected with first, second, and third buses B10, B20, and B22, and may be connected with the first and second processors 210 and 310. A first port of the multi-port MRAM 110 may be connected to the first processor 210 being a baseband processor through the first bus B10, and a second port thereof may be connected to the second processor 310 being an application processor through the second bus B20. Also, a third port of the multi-port MRAM 110 may be connected to the second processor 310 through the third bus B22.

Thus, one multi-port MRAM 110 may be a memory device which replaces a storage memory and two DRAMs. The multi-port MRAM 110 may be implemented by a memory device in FIG. 5.

The multi-port MRAM 110 of FIG. 20 may include three ports and perform roles of a DRAM and a flash memory. Since the multi-port MRAM 110 operates by a DRAM interface, it may replace a DRAM. Also, since a page open policy is supported and the number of bit line sense amplifiers installed is minimized, a chip size of the multi-port MRAM 110 may be minimized or reduced. Therefore, memory cells may be further formed by a chip size reduced, so that a memory density increases.

Since a selective sensing operation on a selected memory cell is implemented without sensing of all memory cells connected with a word line activated at a page open mode of operation, power consumption and power noise may be minimized or reduced at a memory operation. Thus, the performance of the mobile device using it may be improved, and a battery life may be extended.

Since a resistive memory device is used as two DRAMs and a flash memory, a size of the mobile device may be scaled down, so that a cost necessary to implement a system is reduced. In addition, since it is used without changing interconnection between existing processors including DRAM, the resistive memory device may be replaced without modification. Thus, the compatibility may be bettered.

An interface of the first bus B10 may be a volatile memory interface, and the first port may receive first packet data DQ1/ADDR1/CMD1 generated from the first processor 210 to transfer it to an internal circuit block of the multi-port MRAM 110. Also, the first port may provide first data of the multi-port MRAM 110 to the first processor 210. In this case, the first data may be parallel data.

An interface of the third bus B22 may be a volatile memory interface, and the third port may receive third packet data DQ3/ADDR3/CMD3 generated from the second processor 310 to transfer it to an internal circuit block of the multi-port MRAM 110. Also, the third port may provide third data of the multi-port MRAM 110 to the second processor 310.

In this case, the first and third data may be serial data or parallel data. A clock generator (not shown) may generate a first internal clock signal ICLK1 and a third internal clock signal ICLK3 based on an external clock signal CLK. In this case, a frequency of the first internal clock signal ICLK1 may be different from that of the third internal clock signal ICLK3.

An interface of the second bus B20 may be a nonvolatile memory (e.g., NAND flash) interface, and the second port may receive second packet data DQ2/ADDR2/CMD2 generated from the second processor 310 to transfer it to an internal circuit block of the multi-port MRAM 110. Also, the second port may provide second data of the multi-port MRAM 110 to the second processor 310. In this case, the second data may be serial or parallel data.

In some cases, the first and second processors 210 and 310 and the MRAM 110 may be integrated to a chip or packaged. In this case, the MRAM 110 may be embedded in the mobile device.

In the event that the mobile device is a handheld communications device, the first processor 210 may be connected with the modem 700 which transmits and receives communications data and modulates and demodulates data.

A NOR or NAND flash memory may be additionally connected to the first processor 210 or the second processor 310 to store mass information.

The display unit 410 may have a liquid crystal having a backlight, a liquid crystal having an LED light source, or a touch screen (e.g., OLED). The display unit 410 may be an output device for displaying images (e.g., characters, numbers, pictures, etc.) in color.

There is described an example in which the mobile device is a mobile communications device. In some cases, the mobile device may be used as a smart card by adding or removing components.

The mobile device may be connected with an external communications device through a separate interface. The communications device may be a DVD player, a computer, a set top box (STB), a game machine, a digital camcorder, or the like.

The camera unit 600 may include a camera image processor (CIS), and may be connected with the second processor 310.

Although not shown in FIG. 20, the mobile device may further include an application chipset, a camera image processor (CIS), a mobile DRAM, and so on.

An MRAM chip or a flash memory chip may be mounted independently or using various packages. For example, a chip may be packed by a package such as PoP (Package on Package), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), or the like.

In FIG. 20, there is illustrated an example in which an MRAM is installed at the mobile device. However, a variety of nonvolatile memories may be used instead of the MRAM.

The nonvolatile memory may store various types of data information such as texts, graphics, software codes, and so on.

The nonvolatile memory device may be EEPROM (Electrically Erasable Programmable Read-Only Memory), STT-MRAM (Spin-Transfer Torque MRAM), CBRAM (Conductive bridging RAM), FeRAM (Ferroelectric RAM), PRAM (Phase change RAM) called OUM (Ovonic Unified Memory), RRAM or ReRAM (Resistive RAM), nanotube RRAM, PoRAM (Polymer RAM), NFGM (Nano Floating Gate Memory), holographic memory, molecular electronics memory device), or insulator resistance change memory.

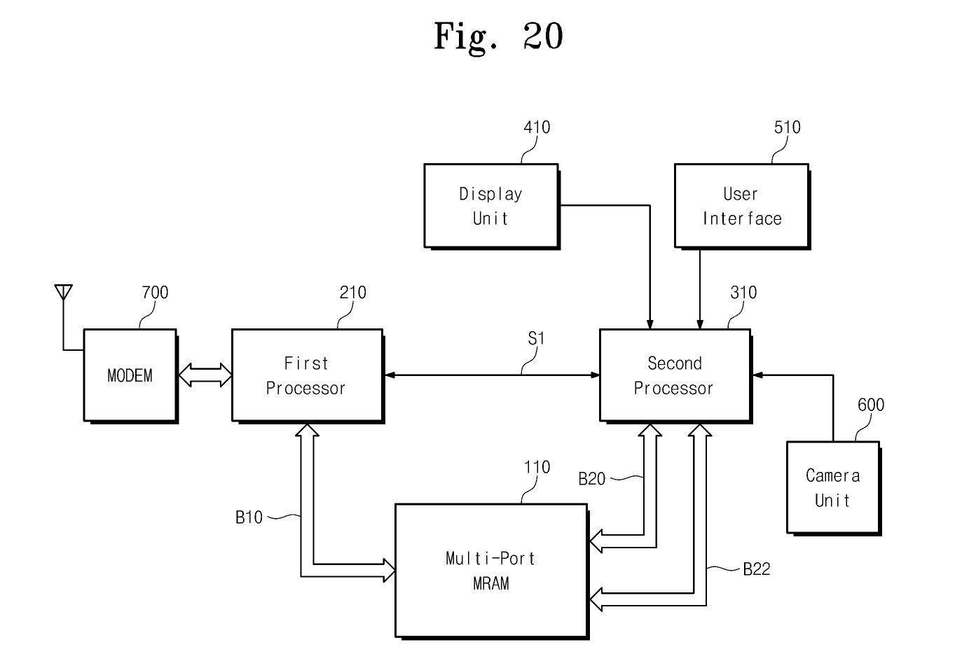

FIG. 21 is a block diagram schematically illustrating a smart card according to an embodiment of the inventive concept.

Referring to FIG. 21, a smart card 10 may include a memory controller 14 and a semiconductor memory device 12. Herein, the semiconductor memory device 12 may be an MRAM, for example. The memory controller 14 may write data necessary for the smart card 10 at the MRAM 12. At an input of a read command, the MRAM 12 may read data stored at a selected magnetic memory cell by applying a read current to the selected magnetic memory cell in one of a first direction and a second direction and sensing the flow strength of the read current.

In FIG. 21, the MRAM 12 may be implemented by a resistive memory device of FIG. 5. Since the MRAM 12 is configured such that a page open policy is supported and the number of bit line sense amplifiers is minimized, it may be mounted within the smart card without a size trouble. Also, since a selective sensing operation is implemented at a page open mode of operation, a read error may be minimized. Thus, the performance of the smart card using it may be improved.

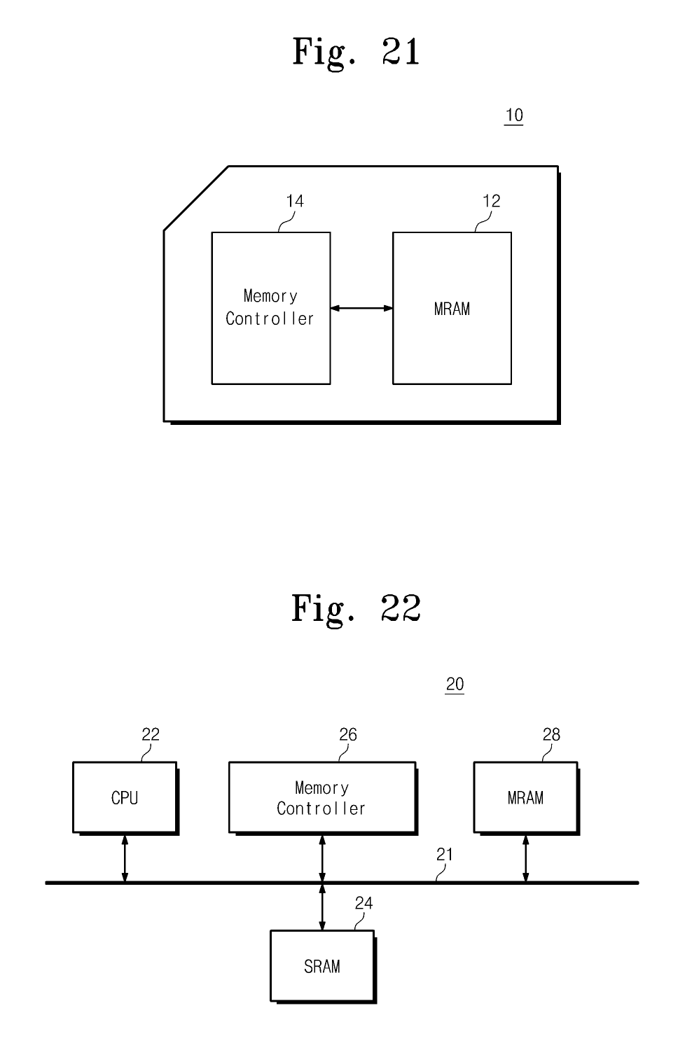

FIG. 22 is a block diagram schematically illustrating a memory system according to an embodiment of the inventive concept.

Referring to FIG. 22, a memory system 20 may include a CPU 22, an SRAM 24, a memory controller 26, and an MRAM 28 which are electrically connected with a bus 21. Herein, the MRAM 28 may have a read operation and a write operation as described according to the spirit of the inventive concept.

N-bit data (N being an integer being 1 or more than 1) processed or to be processed by the CPU 22 may be stored at the MRAM 28 through the memory controller 26. Although not shown in FIG. 22, the memory system 20 may further comprise an application chipset, a camera image processor (CIS), a mobile DRAM, and so on. The memory controller 26 and the resistive memory device 28 may constitute a solid state drive (SSD), for example.

As described with reference to figures according to embodiments of the inventive concept, since a chip size of the MRAM 28 is scaled down and the MRAM 28 has improved read and write operations, the reliability of the memory system may be improved.

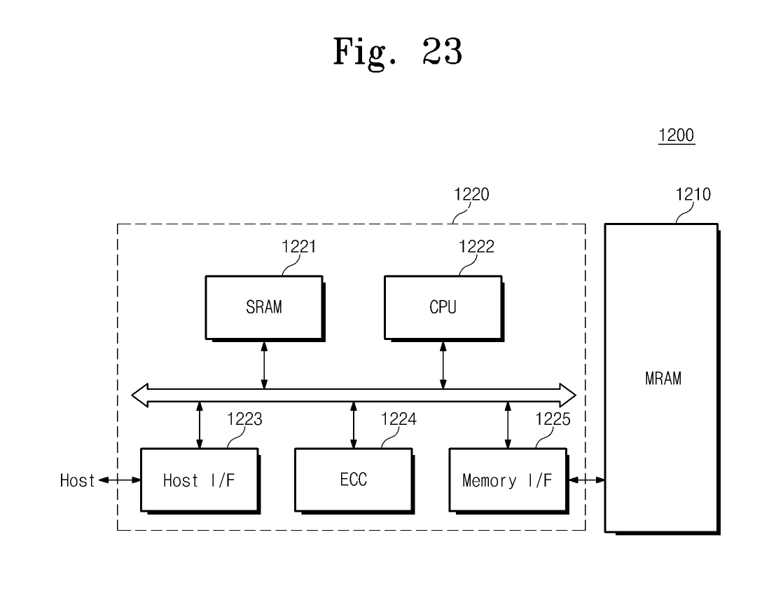

FIG. 23 is a block diagram schematically illustrating a memory card according to an embodiment of the inventive concept.

An MRAM 1210 according to an embodiment of the inventive concept may be applied to a memory card 1200. For example, the memory card 1200 may include a memory controller 1220 which controls data exchange between a host and the MRAM 1210 overall.

In the memory controller 1220, an SRAM 1221 may be used as a working memory of a CPU 1222. A host interface 1223 may have the data exchange protocol of the host connected with the memory card 1200. An ECC block 1224 may detect and correct an error included in data read from the resistive memory device 1210. A memory interface 1225 may provide an interface between the resistive memory device 1210 and the memory controller 1220. The CPU 1222 may perform an overall control operation for data exchange of the memory controller 1220.

As described with reference to figures according to embodiments of the inventive concept, since a chip size of the MRAM 1210 is scaled down and the MRAM 28 has improved read and write operations, the performance of the memory card may be improved.

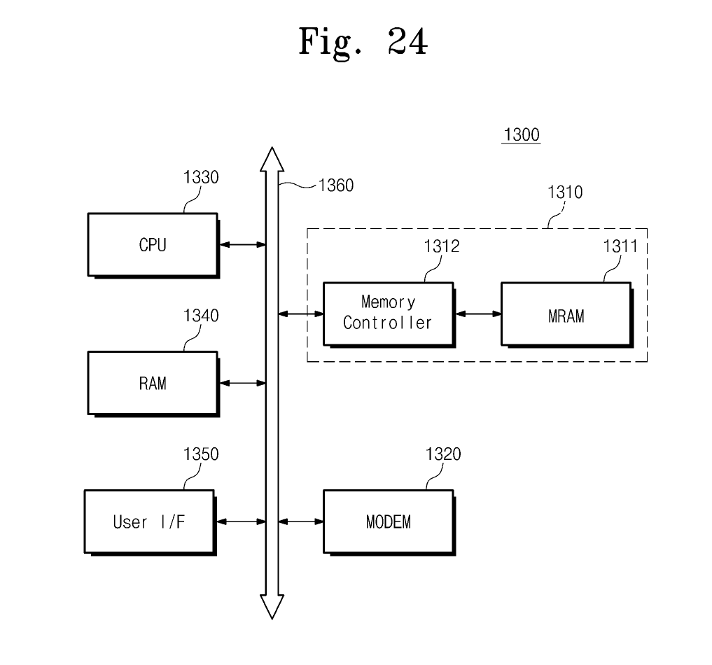

FIG. 24 is a block diagram schematically illustrating an information processing system according to an embodiment of the inventive concept.

Referring to FIG. 24, an information processing system 1300 may include a memory system 1310 which has an MRAM 1311 according to an embodiment of the inventive concept. The information processing system 1300 may include a mobile device or a computer. For example, the information processing system 1300 may include the memory system 1310, a MODEM 1320, a CPU 1330, a RAM 1340, and a user interface 1350 which are electrically connected with a system bus 1360. Data processed by the CPU 1330 or data input from an external device may be stored at the memory system 1310. The information processing system 1300 may further comprise a solid state disk, a camera image sensor, an application chipset, and so on. For example, the memory system 1310 may be formed of a solid state drive (SSD). In this case, the information processing system 1300 may store mass data at the memory system 1310 stably and reliably.

Since the MRAM 1311 is configured such that the number of bit line sense amplifiers is minimized and has improved read and write operations, the performance of the information processing system may be improved.

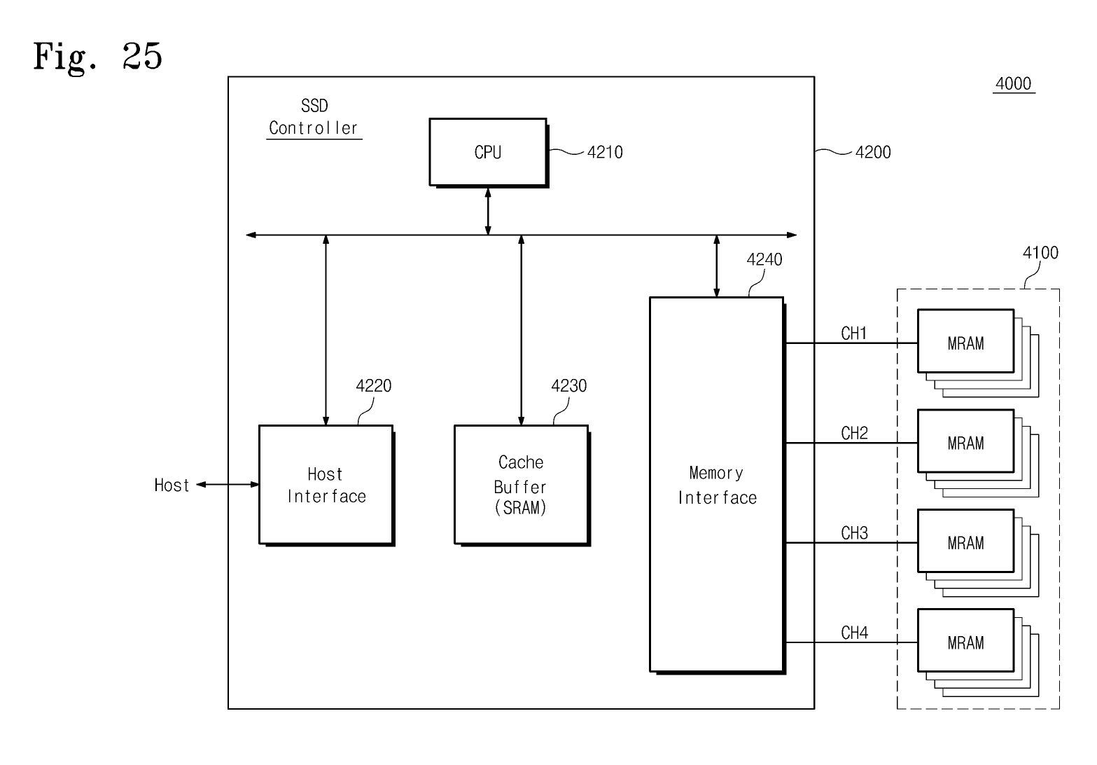

FIG. 25 is a block diagram schematically illustrating a solid state drive (SSD) according to an embodiment of the inventive concept.

The inventive concept is applicable to a solid state drive (hereinafter, referred to as SSD).

Referring to FIG. 25, a SSD 4000 may include an MRAM module 4100 and an SSD controller 4200.

MRAM chips in the MRAM module 4100 may have the same structure and operation as described with reference to FIG. 1, 3, or 5.

The SSD controller 4200 may control the MRAM modules formed of a plurality of MRAMs. The SSD controller 4200 may include a CPU 4210, a host interface 4220, a cache buffer 4230, and a memory interface 4240. The host interface 4220 may exchange data with a host in the ATA protocol manner under the control of the CPU 4210. Herein, the host interface 4220 may be one of a SATA (Serial Advanced Technology Attachment) interface, a PATA (Parallel Advanced Technology Attachment) interface, and an ESATA (External SATA) interface. Data input through the host interface 4220 from the host or to be transferred through the host interface 4220 to the host may be directly transferred to the cache buffer 4230 without passing through a CPU bus under the control of the CPU 4210.

The cache buffer 4230 may temporarily store data transferred between an external device and the MRAM module 4100. The cache buffer 4230 may be used to store programs executed by the CPU 4210. The cache buffer 4230 may be a type of buffer memory, and may be formed of an SRAM. In FIG. 25, there is illustrated an example in which the cache buffer 4230 is included in the SSD controller 4200. However, the inventive concept is not limited thereto. For example, the cache buffer 4230 may be provided outside the SSD controller 4200.

The memory interface 4240 may provide an interface between the MRAM module 4100 used as a storage device and the SSD controller 4200. The memory interface 4240 may be configured to support a PRAM module or an RRAM module as well as an MRAM module.

A resistive memory cell in the MRAM module 4100 or another module may be a single-level memory cell storing 1-bit data or a multi-level memory cell storing multi-bit data.

As described with reference to figures according to embodiments of the inventive concept, since a chip size of each MRAM in the MRAM module 4100 is scaled down and each MRAM has improved read and write operations, the performance of the SSD may be improved. Further, it is possible to reduce a manufacturing cost of the SSD.

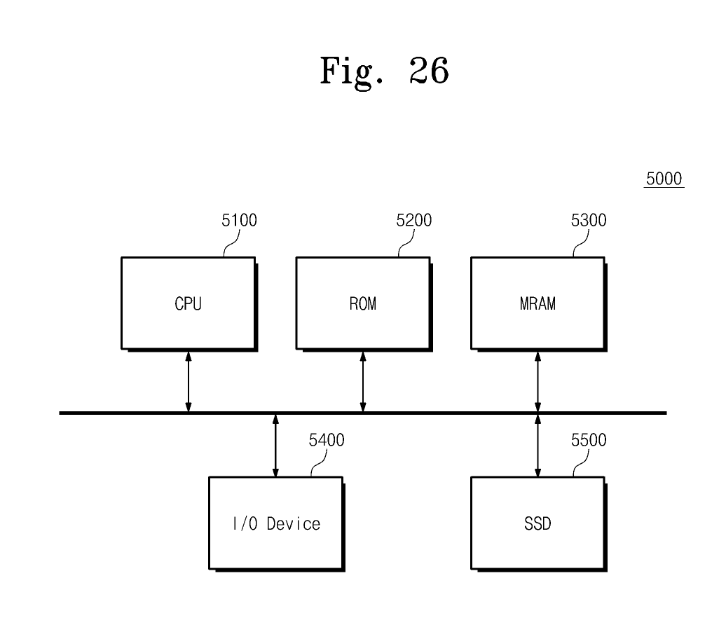

FIG. 26 is a block diagram schematically illustrating a computing system according to an embodiment of the inventive concept.

A computing system of FIG. 26 may include an SSD 400 of FIG. 25.

Referring to FIG. 26, a computing system 5000 may include a CPU 5100, a ROM 5200, an MRAM 5300, an input/output device 5400, and an SSD 5500.

The CPU 5100 may be connected to a system bus. The ROM 5200 may be used to store data necessary to operate the computing system 5000. Such data may include a start command sequence, a BIOS sequence, or the like. The MRAM 5300 may temporarily store task data generated at an operation of the CPU 5100. As described with reference to figures according to embodiments of the inventive concept, since a chip size of the MRAM 5300 is scaled down and the MRAM 5300 has improved read and write operations, the MRAM 5300 may function as a memory for replacing a DRAM.

In the input/output device 5400, for example, a keyboard, a pointing device (e.g., a mouse), a monitor, a modem, and the like may be connected with a system bus through an input/output device interface.

Although not illustrated in FIG. 26, the computing system 5000 may further include an application chipset, a camera image processor (CIS), a mobile DRAM, and so on.

The SSD 5500 may be a readable storage device, and may be formed of an SSD 4000 of FIG. 25.

The computing system 5000 may include an MRAM compatible with a DRAM. As described with reference to figures according to embodiments of the inventive concept, a chip size of the MRAM is scaled down and the MRAM has improved read and write operations. Thus, the performance of the computing system 5000 may be improved. Further, it is possible to reduce a manufacturing cost. Still further, power consumption may be minimized or reduced.

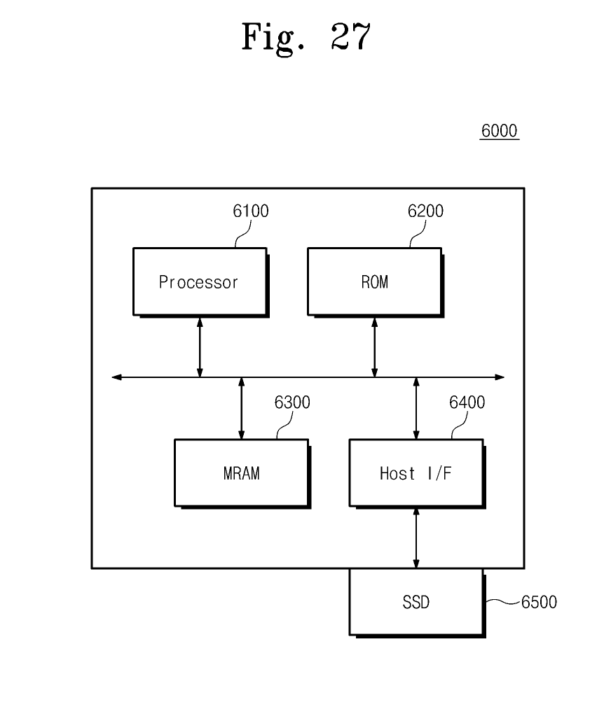

FIG. 27 is a block diagram schematically illustrating an electronic device according to an embodiment of the inventive concept.

Referring to FIG. 27, an electronic device 6000 may include a processor 6100, a ROM 6200, an MRAM 6300, a flash interface 6400, and an SSD 6500.

The processor 6100 may access the MRAM 6300 to execute firmware codes or any code. The processor 6100 may access the ROM 6200 to execute fixed command sequences such as a start command sequence, a BIOS sequence, and so on. The flash interface 6400 may interface between the electronic device 6000 and the SSD 6500. The SSD 6500 may be detachable from the electronic device 6000.

In FIG. 27, the MRAM 6300 may be accessed by the processor 6100 through a DRAM interface. Thus, the MRAM 6300 may perform a page open mode of operation by support of a page open policy. In this case, there may be performed a selective sensing operation in which only necessary cell data is selectively sensed after an input of a read command. Thus, the processor 6100 may use the MRAM 6300 like a DRAM without burden associated with refresh control.

Thus, as described above, since effects according to an embodiment of the inventive concept are provided, the performance of the electronic device may be improved.

The electronic device 6000 may be a cellular phone, a PDA, a digital camera, a camcorder, a handheld audio playback device (e.g., MP3 player), a PMP, and so on.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative. For example, various changes and modifications on a memory cell array structure and driving timings of read and write operations may be made without departing from the spirit and scope of the present invention.

What is claimed is:

1. A method of controlling a read operation of a resistive memory device, the method comprising:
receiving a first command;
activating a first word line of a plurality of word lines in response to receiving the first command;
receiving a second command after the first command;
in response to receiving a second command, sensing data of only a first portion of memory cells connected to the first word line while the first word line remains activated; and
outputting the sensed data as read data.

2. The method of claim 1, wherein a first time period from an input of the first command until an input of the second command is shorter than a second time period from an input of the second command until an output of the read data.

3. The method of claim 1, further comprising:
receiving a third command after receiving the second command;
in response to receiving a third command, sensing data of only a second portion of memory cells operatively connected to the first word line while the first word line is activated in response to the first command.

4. The method of claim 1, wherein sensing data comprises sensing data with a bit line sense amplifier that is shared by plural bit lines.

5. The method of claim 4, further comprising connecting the bit line sense amplifier to one of the plural bit lines in response to the second command.

6. The method of claim 1, wherein the first word line is activated after a column address is received.

7. The method of claim 1, wherein the memory cells are magnetic memory cells.

8. The method of claim 1, wherein the first portion of the first word line is selected from plural portions of the first word line by decoding at least a part of row address.

9. A method of controlling a read operation of a resistive memory device, the method comprising:
activating a first word line, identified with a first command, from among a plurality of word lines;
sensing data of only a first portion of memory cells connected to the activated first word line, the first portion of memory cells being selected by a page selection signal, from among all memory cells connected with the activated first word line; and
outputting the sensed data as read data in response to a column selection control signal.

10. The method of claim 9, wherein the column selection control signal is activated by decoding at least a part of a column address.

11. The method of claim 9, wherein a first time period from an input of the first command until an input of the second command is shorter than a second time period from an input of the second command until an output of the read data.

12. The method of claim 9, further comprising, while the first word line is activated, receiving a sequence of second commands and sequentially sensing respective portions of memory cells connected to the activated first word line in response to corresponding ones of the received sequence of second commands.

13. The method of claim 9, wherein the sensing of data of the first portion of memory cells connected to the activated first word line comprises sensing data with a bit line sense amplifier that is shared by bit lines belonging to different pages.

14. The method of claim 9, wherein the sensing of data of the first portion of memory cells connected to the activated first word line comprises sensing data with a plurality of bit line sense amplifiers each being connected to bit lines of plural pages, wherein the bit line sense amplifiers are distributed throughout a sub memory cell array.

15. The method of claim 13, wherein the first word line is activated after a column address is received.

16. The method of claim 13, wherein the memory cell is an STT-MRAM cell.

17. The method of claim 13, wherein the sensing of data of the first portion of memory cells connected to the activated first word line comprises sensing data with a bit line sense amplifier that is shared by bit lines belonging to different pages, and wherein the first word line and a bit line connected to the bit line sense amplifier are selected by decoding at least a part of a row address.

18. A method of controlling a resistive memory device, the method comprising:
activating at least a first of a plurality of word lines in response to a first command;
in response to a received second command and received write data, activating a column selection control signal; and
driving bit line sense amplifiers such that the write data is stored at memory cells of the first word line corresponding to a selected page identified with the second command, from among all memory cells connected with the activated word line.

19. The method of claim 18,
wherein the bit line sense amplifiers are enabled by corresponding bit line sense amplifier enable signals, and
wherein the column selection control signal and the bit line sense amplifier enable signals are activated at a same time period.

20. The method of claim 18, wherein an operation of sensing cell data stored in the memory cells is inhibited in response to receiving the second command.

21. The method of claim 18, further comprising, while the first word line is activated in response to the first command, receiving a third command, and in response to the third command, sensing a first page of data of the first word line of plural pages of the first word line.

22. The method of claim 18, further comprising, while the first word line is activated in response to the first command, receiving a series of third commands, and in response to each of the third commands, sensing a corresponding page of data of the first word line of plural pages of the first word line.

23. The method of claim 18, wherein each of the bit line sense amplifiers is connected to bit lines of different pages.

24. The method of claim 18, wherein memory cells corresponding to the selected page are selected by decoding at least a part of a row address.

25. A resistive memory device, comprising:
a memory cell array including a plurality of memory banks each having a plurality of sub memory cell arrays where memory cells are disposed at intersections of word lines and bit lines;
a plurality of bit line sense amplifiers each configured to be connected to bit lines of different pages, the bit line sense amplifiers being distributed through each of the sub memory cell arrays;
a first decoder configured to generate a page selection signal such that, at least within a first sub memory cell array of the sub memory cell arrays, each of the plurality of bit line sense amplifiers is connected to a corresponding bit line of a first page of the different pages; and
a second decoder configured to generate a word line selection signal for selecting one of the word lines and to generate a sub block selection signal for selectively connecting a sensing output terminal of each of the bit line sense amplifiers with a corresponding input/output line.

26. The resistive memory device of claim 25, wherein the first decoder is configured to generate the page selection signal by decoding at least a part of a part of row address bits.

27. The resistive memory device of claim 25, wherein the second decoder is a decoder configured to decode a row address and a column address.

28. The resistive memory device of claim 25, wherein the bit line sense amplifiers are configured to be independently enabled in response to a receipt of a column address and a read command such that data of memory cells connected with corresponding bit lines selected by the page selection signal is sensed.

29. A method of reading a resistive memory device, the memory device comprising a plurality of word lines, a plurality of bit lines, and memory cells each connected with one of the word lines and one of the bit lines, the method comprising:
activating a first word line of the plurality of word lines, the first word line being connected to a plurality of resistive memory cells;
during a first time period, sensing data of only a first group of the resistive memory cells connected to the first word line while the first word line is activated; and
during a second time period, sensing data of only a second group of the resistive memory cells connected to the first word line.

30. The method of claim 29, further comprising:
selectively connecting a plurality of bit line sense amplifiers to a first group of bit lines connected to the first group of resistive memory cells to sense data of the first group of resistive memory cells; and
selectively connecting the plurality of bit line sense amplifiers to a second group of bit lines connected to the second group of resistive memory cells to sense data of the second group of resistive memory cells.

31. The method of claim 29, further comprising:
receiving first, second and third commands,
wherein activation of the first word line is responsive to the first command,
wherein selectively connecting the plurality of bit line sense amplifiers to the first group of bit lines is responsive to the second command, and
wherein selectively connecting the plurality of bit line sense amplifiers to the second group of bit lines is responsive to the third command.
